(19) United States
(12) Patent Application Publication
(10) Pub. No.: US 2023/0247778 A1
(43) Pub. Date: Aug. 3, 2023

(54) ELECTRONIC DEVICE

(71) Applicant: Samsung Display Co., Ltd., Yongin-si (KR)

(72) Inventors: YONG-KWAN KIM, Yongin-si (KR); YONGHYUCK LEE, Cheonan-si (KR); HONGKWAN LEE, Yongin-si (KR); HYUNJUN CHO, Seoul (KR); SOHRA HAN, Cheonan-si (KR)

(21) Appl. No.: 17/950,438

(22) Filed: Sep. 22, 2022

(30) Foreign Application Priority Data
Feb. 3, 2022 (KR) 10-2022-0014289

(51) Int. Cl. H05K 5/02; H04M 1/02

(52) U.S. Cl. CPC H05K 5/02; H04M 1/0268

(57) ABSTRACT

An electronic device includes a display layer and a support part disposed under the display layer. The support part includes a first support portion having first and second surfaces defined thereon, and a second support portion facing the second surface. The first support portion includes a first material, the first surface faces the display layer, and the first surface is closer to the display layer than the second surface is. The second support portion includes a second material different from the first material. The first material includes glass fiber reinforced plastic.

This application claims priority to Korean Patent Application No. 10-2022-0014289, filed on Feb. 3, 2022, and all the benefits accruing therefrom under 35 U.S.C. § 119, the content of which in its entirety is herein incorporated by reference.

### BACKGROUND

### 1. Field

Embodiments of the disclosure described herein relate to an electronic device having improved display quality.

### 2. Description of the Related Art

In general, electronic devices which provide an image to a user, such as a smart phone, a digital camera, a notebook computer, a navigation unit, a smart television, and the like include a display device for displaying an image. The electronic device generates an image and provides the image to the user through a display screen.

Recently, various types of electronic devices are being developed with the development of electronic device technologies. For example, various flexible electronic devices that can be curved, folded, or rolled are being developed. The flexible electronic devices may be easy to carry and may improve user convenience.

### SUMMARY

Embodiments of the disclosure provide an electronic device having improved display quality.

According to an embodiment, an electronic device includes a display layer and a support part disposed under the display layer. In such an embodiment, the support part includes a first support portion having first and second surfaces defined thereon and a second support portion facing the second surface. In such an embodiment, the first support portion includes a first material, the first surface faces the display layer, and the first surface is closer to the display layer than the second surface is. In such an embodiment the second portion includes a second material different from the first material. In such an embodiment, the first material includes glass fiber reinforced plastic (GFRP).

In an embodiment, the glass fiber reinforced plastic may include a first resin and a glass fiber disposed in the first resin.

In an embodiment, the glass fiber may include a first fiber extending in a first direction and a second fiber extending in a second direction crossing the first direction.

In an embodiment, the second material may include carbon fiber reinforced plastic (CFRP).

In an embodiment, the carbon fiber reinforced plastic may include a second resin and a carbon fiber disposed in the second resin.

In an embodiment, the carbon fiber may extend in the first direction.

In an embodiment, the first material may have higher surface energy than the second material.

In an embodiment, the display layer may have a first area, a second area, and a third area defined therein. In such an embodiment, the second area may be spaced apart from the first area in a first direction, and the third area may be spaced apart from the first area in the first direction with the second area therebetween. In such an embodiment, the support part may be disposed under the first area, the second area, and the third area and may have a continuous shape. In such an embodiment, a pattern hole may be defined in the first support portion overlapping the second area when viewed in a plan view.

In an embodiment, the pattern hole may include a plurality of pattern holes. In such an embodiment, the plurality of pattern holes may be spaced apart from each other in the first direction and a second direction crossing the first direction. In such an embodiment, each of the plurality of pattern holes may be defined through at least part of the first support portion in a thickness direction of the first support portion.

In an embodiment, the second support portion may make contact with the first support portion.

In an embodiment, the support part may further include a third support portion disposed under the second support portion.

In an embodiment, the third support portion may include the first material.

In an embodiment, the third support portion may be spaced apart from the first support portion with the second support portion therebetween.

In an embodiment, a first curing temperature of the first material may be higher than a second curing temperature of the second material.

In an embodiment, the second material may include fiber reinforced plastic (FRP), and the second support portion may include a plurality of layers.

In an embodiment, the first support portion may be closer to the display layer than the second support portion is.

According to an embodiment, an electronic device includes a display layer having a folding area and a non-folding area defined therein and a support part disposed under the display layer. In such an embodiment, the folding area is foldable about a folding axis, and the non-folding area is adjacent to the folding area. In such an embodiment, the support part includes a first support portion having first and second surfaces defined thereon and a second support portion facing the second surface. In such an embodiment, the first support portion includes a first material, the first surface faces the display layer, and the first surface is closer to the display layer than the second surface is. In such an embodiment the second portion includes a second material different from the first material. In such an embodiment, the first material includes a glass fiber, and the second material includes a carbon fiber.

In an embodiment, the first material may further include a first resin, and the glass fiber may include a first fiber extending in a first direction and a second fiber extending in a second direction crossing the first direction.

In an embodiment, the glass fiber may be disposed in the first resin.

In an embodiment, the second material may further include a second resin, and the carbon fiber may extend in a first direction.

In an embodiment, the carbon fiber may be disposed in the second resin.

In an embodiment, the first material may have higher surface energy than the second material.

In an embodiment, the second support portion may make contact with the first support portion.

In an embodiment, the support part may further include a third support portion disposed under the second support portion.

In an embodiment, the third support portion may include the first material.

In an embodiment, a first curing temperature of the first material may be higher than a second curing temperature of the second material.

### BRIEF DESCRIPTION OF THE DRAWINGS

The above and other features of the disclosure will become apparent by describing in detail embodiments thereof with reference to the accompanying drawings, in which:

FIG. 1A is a perspective view illustrating an electronic device in a flat state according to an embodiment of the disclosure;

FIG. 1B is a perspective view illustrating the electronic device illustrated in FIG. 1A in an in-folding process;

FIG. 1C is a plan view illustrating the electronic device illustrated in FIG. 1A in an in-folded state;

FIG. 1D is a perspective view illustrating an electronic device in an out-folding process according to an embodiment of the disclosure;

FIG. 2 is an exploded perspective view of the electronic device according to an embodiment of the disclosure;

FIG. 3A is a perspective view illustrating an electronic device in a flat state according to an embodiment of the disclosure;

FIG. 3B is a perspective view illustrating the electronic device illustrated in FIG. 3A in a folding process;

FIG. 4 is an exploded perspective view of the electronic device according to an embodiment of the disclosure;

FIG. 5 is a perspective view of an electronic device according to an embodiment of the disclosure;

FIG. 6 is an exploded perspective view of the electronic device according to an embodiment of the disclosure;

FIG. 7 is a block diagram of an electronic device according to an embodiment of the disclosure;

FIG. 8 is a cross-sectional view of a display module according to an embodiment of the disclosure;

FIG. 9 is a cross-sectional view of the display module according to an embodiment of the disclosure;

FIG. 10 is a cross-sectional view of the electronic device taken along line I-I′ of FIG. 1A according to an embodiment of the disclosure;

FIG. 11 is a cross-sectional view illustrating a folded state of the electronic device according to an embodiment of the disclosure;

FIG. 12 is a perspective view illustrating a support part according to an embodiment of the disclosure;

FIG. 13 is a plan view illustrating an area BB of FIG. 12 according to an embodiment of the disclosure;

FIG. 14 is a cross-sectional view taken along line II-IF of FIG. 12 according to an embodiment of the disclosure;

FIG. 15 is a view illustrating a first material of the support part according to an embodiment of the disclosure;

FIG. 16 is a view illustrating a second material of the support part according to an embodiment of the disclosure;

FIG. 17A illustrates an upper surface of a first support portion according to an embodiment of the disclosure;

FIG. 17B is a view illustrating the surface quality of the upper surface of the first support portion according to an embodiment of the disclosure;

FIG. 18A illustrates an upper surface of a second support portion according to an embodiment of the disclosure;

FIG. 18B is a view illustrating the surface quality of the upper surface of the second support portion according to an embodiment of the disclosure;

FIG. 19 is a graph depicting the forming temperature of the support part over process time according to an embodiment of the disclosure;

FIG. 20 is a cross-sectional view of a support part according to an alternative embodiment of the disclosure;

FIG. 21 is a cross-sectional view of a support part according to another alternative embodiment of the disclosure; and

FIG. 22 is a cross-sectional view of a support part according to another alternative embodiment of the disclosure.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

In this specification, when it is mentioned that a component (or, an area, a layer, a part, etc.) is referred to as being “on”, “connected to” or “coupled to” another component, this means that the component may be directly on, connected to, or coupled to the other component or a third component may be therebetween.

Identical reference numerals refer to identical components. Additionally, in the drawings, the thicknesses, proportions, and dimensions of components are exaggerated for effective description. As used herein, the term “and/or” includes all of one or more combinations defined by related components.

Terms such as first, second, and the like may be used to describe various components, but the components should not be limited by the terms. The terms may be used only for distinguishing one component from other components. For example, without departing the scope of the disclosure, a first component may be referred to as a second component, and similarly, the second component may also be referred to as the first component.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items.

In addition, terms such as “below”, “under”, “above”, and “over” are used to describe a relationship of components illustrated in the drawings. The terms are relative concepts and are described based on directions illustrated in the drawing.

It should be understood that terms such as “comprise”, “include”, and “have”, when used herein, specify the presence of stated features, numbers, steps, operations, components, parts, or combinations thereof, but do not preclude the presence or addition of one or more other features, numbers, steps, operations, components, parts, or combinations thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the disclosure will be described in detail with reference to the accompanying drawings.

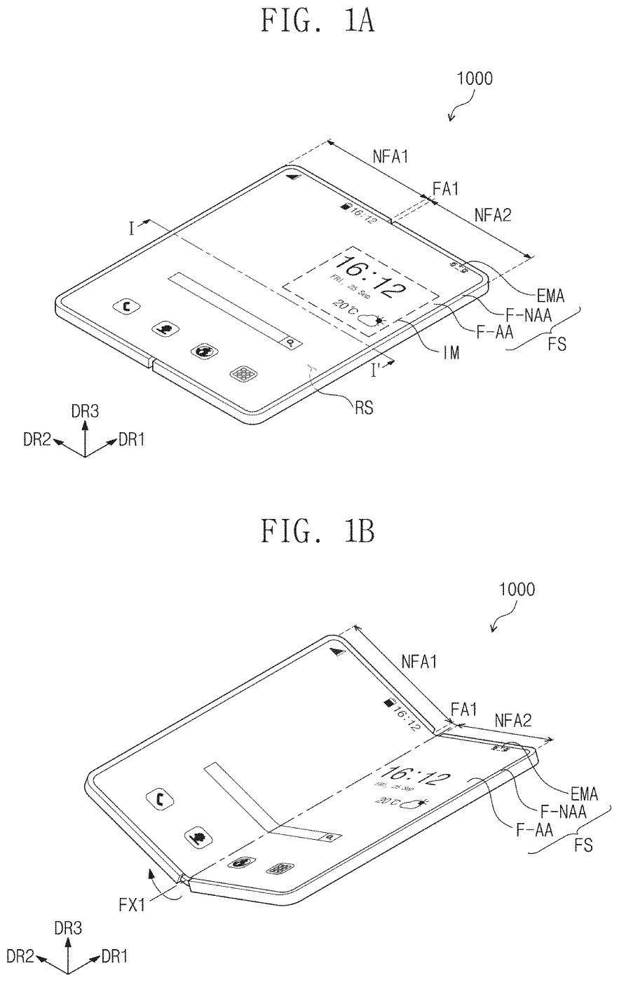

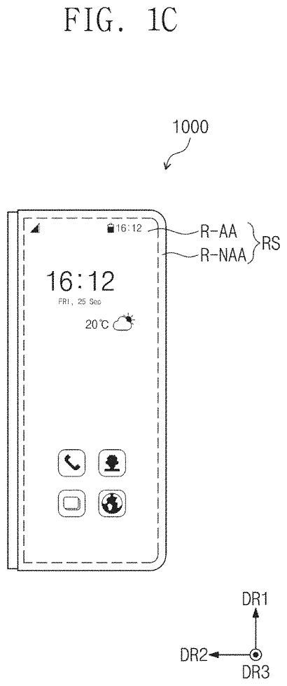

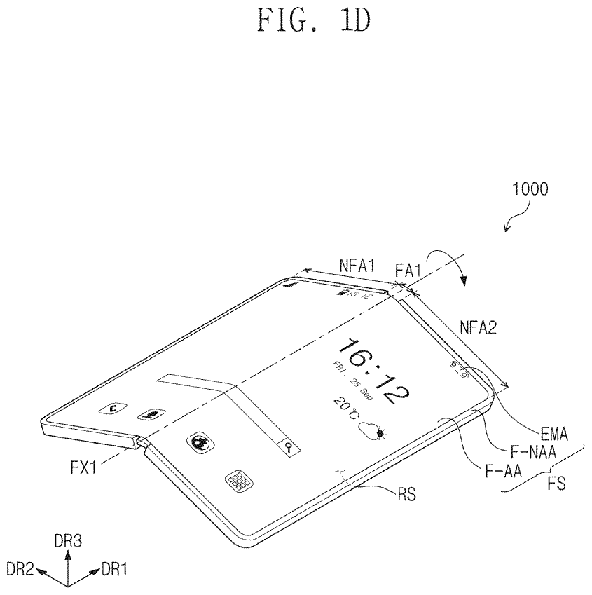

FIG. 1A is a perspective view illustrating an electronic device in a flat state according to an embodiment of the disclosure.

Referring to FIG. 1A, an embodiment of the electronic device 1000 may be a device activated in response to an electrical signal. In an embodiment, for example, the electronic device 1000 may be a mobile phone, a tablet computer, a car navigation unit, a game machine, or a wearable device, but is not limited thereto. In FIG. 1A, an embodiment where the electronic device 1000 is a mobile phone is illustrated.

The electronic device 1000 may include a first display surface FS defined by a first direction DR1 and a second direction DR2 crossing the first direction DR1. The electronic device 1000 may provide an image IM to a user through the first display surface FS. The image IM may include a still image as well as a dynamic image. In FIG. 1A, an embodiment where the image IM includes a clock window and icons is illustrated. The electronic device 1000 may display the image IM in a third direction DR3 on the first display surface FS parallel to the first direction DR1 and the second direction DR2. The front surfaces (or, the upper surfaces) and the rear surfaces (or, the lower surfaces) of components may be defined based on the direction in which the image IM is displayed. The front surfaces and the rear surfaces may be opposite each other in the third direction DR3, and the normal directions of the front surfaces and the rear surfaces may be parallel to the third direction DR3.

The first display surface FS may include a first active area F-AA and a first peripheral area F-NAA. An electronic module area EMA may be included in the first active area F-AA. The electronic device 1000 may display the image IM through the first active area F-AA. In an embodiment, the first active area F-AA may sense various forms of external inputs. The first peripheral area F-NAA may be adjacent to the first active area F-AA. The first peripheral area F-NAA may have a predetermined color. The first peripheral area F-NAA may surround the first active area F-AA. Accordingly, the shape of the first active area F-AA may be substantially defined by the first peripheral area F-NAA. However, this is illustrative, and alternatively, the first peripheral area F-NAA may be disposed adjacent to only one side of the first active area F-AA, or may be omitted. The electronic device 1000 according to an embodiment of the disclosure may include various forms of active areas and is not limited to any one embodiment.

The electronic device 1000 may include a second display surface RS. The second display surface RS may be defined as a surface facing away from at least a portion of the first display surface FS. That is, the second display surface RF may be defined as a portion of the rear surface of the electronic device 1000. When the electronic device 1000 is in an in-folded state, the second display surface RS may be visible to the user.

The electronic device 1000 may sense an external input applied from the outside. The external input may include various forms of inputs provided from outside the electronic device 1000. In an embodiment, for example, the external input may include not only a touch of a part of the user's body (e.g., the user's hand) on the electronic device 1000 but also an external input (e.g., hovering) applied by an input tool or a part of the user's body that is proximate to, or spaced a predetermined distance apart from, the electronic device 1000. In an embodiment, the external input may have various forms such as force, pressure, temperature, light, and the like.

Although the first to third directions DR1 to DR3 are illustrated in FIG. 1A and the following drawings, the directions indicated by the first to third directions DR1, DR2, and DR3 described in this specification may be relative concepts and may be changed to different directions. Furthermore, the directions indicated by the first to third directions DR1, DR2, and DR3 may be referred to as the first to third directions, and identical reference numerals may be used to refer to the directions.

The electronic device 1000 may include at least one folding area FA1 and non-folding areas NFA1 and NFA2 adjacent to the folding area FA1. The non-folding areas NFA1 and NFA2 may be spaced apart from each other with the folding area FA1 therebetween.

FIG. 1B is a perspective view illustrating the electronic device illustrated in FIG. 1A in an in-folding process.

Referring to FIG. 1B, an embodiment of the electronic device 1000 may be folded about a first folding axis FX1. The first folding axis FX1 may be an imaginary axis extending in the first direction DR1. The first folding axis FX1 may be parallel to the direction of the long sides of the electronic device 1000. The first folding axis FX1 may extend in the first direction DR1 on the first display surface FS.

The non-folding areas NFA1 and NFA2 may be disposed adjacent to the folding area FA1 with the folding area FA1 therebetween. In an embodiment, for example, the first non-folding area NFA1 may be disposed on one side of the folding area FA1 in the second direction DR2, and the second non-folding area NFA2 may be disposed on an opposite side of the folding area FA1 in the second direction DR2.

The electronic device 1000 may be folded about the first folding axis FX1 and may be changed to an in-folded state in which one area of the first display surface FS that overlaps the first non-folding area NFA1 and an opposite area of the first display surface FS that overlaps the second non-folding area NFA2 face each other.

FIG. 1C is a plan view illustrating the electronic device illustrated in FIG. 1A in an in-folded state.

Referring to FIG. 1C, in an embodiment of the electronic device 1000 in the in-folded state, the second display surface RS may be visible to the user. In such an embodiment, the second display surface RS may include a second active area R-AA that displays an image and a second peripheral area R-NAA adjacent to the second active area R-AA. The second active area R-AA may be an area on which an image is displayed and that senses various forms of external inputs. The second peripheral area R-NAA may have a predetermined color. The second peripheral area R-NAA may surround the second active area R-AA. Although not illustrated, the second display surface RS may further include an electronic module area in which an electronic module including various components is disposed, and the disclosure is not limited to any one embodiment.

FIG. 1D is a perspective view illustrating an electronic device in an out-folding process according to an embodiment of the disclosure.

Referring to FIG. 1D, an embodiment of the electronic device 1000 may be folded about the first folding axis FX1 and may be changed to an out-folded state in which one area of the second display surface RS that overlaps the first non-folding area NFA1 and an opposite area of the second display surface RS that overlaps the second non-folding area NFA2 face each other.

However, the disclosure is not limited thereto. The electronic device 1000 may be folded about a plurality of folding axes such that a portion of the first display surface FS and a portion of the second display surface RS face each other, and the number of folding axes and the number of non-folding areas are not particularly limited.

In an embodiment of the disclosure, the electronic device 1000 may be configured in a way such that an in-folding motion and an out-folding motion are repeatedly performed. However, the disclosure is not limited thereto. In an embodiment, the electronic device 1000 may be configured to select one of an unfolding motion, an in-folding motion, and an out-folding motion.

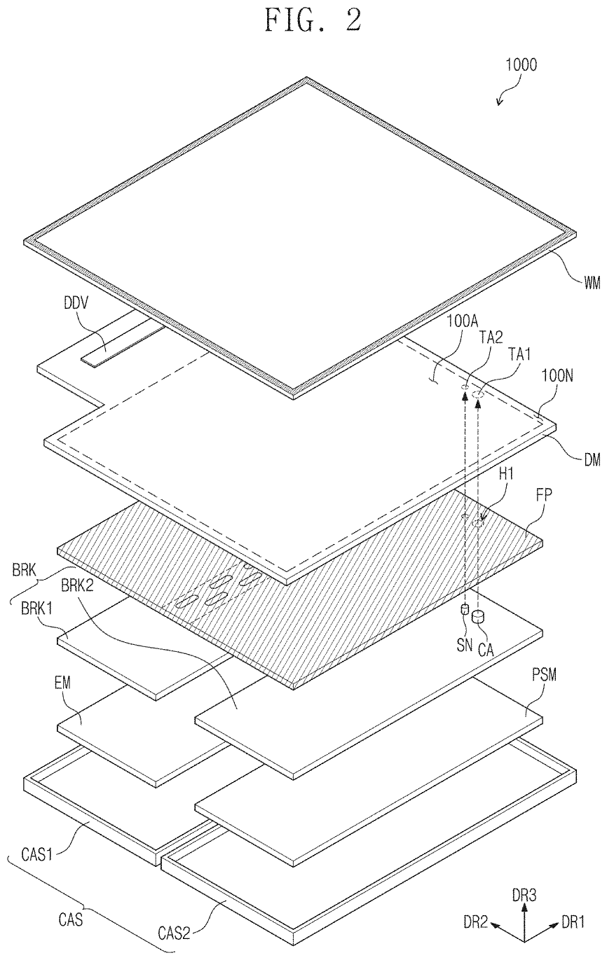

FIG. 2 is an exploded perspective view of the electronic device according to an embodiment of the disclosure.

Referring to FIG. 2, an embodiment of the electronic device 1000 may include a window WM, a display module DM, a support part FP, a camera CA, a sensor SN, a bracket BRK, an electronic module EM, a power supply module PSM, and a case CAS.

The window WM may provide or define the front surface of the electronic device 1000. The window WM may transmit light generated from the display module DM and may provide the light to the user.

The display module DM may have an active area 100A and a peripheral area 100N defined therein. The active area 100A may correspond to the first active area F-AA (refer to FIG. 1A) of the electronic device 1000, and the peripheral area 100N may correspond to the first peripheral area F-NAA (refer to FIG. 1A) of the electronic device 1000. The expression “one area/portion corresponds to another area/portion” used herein may mean that the areas/portions overlap each other and is not limited to having a same area as each other.

The display module DM may have a first transmissive area TA1 and a second transmissive area TA2 defined therein. The first transmissive area TA1 and the second transmissive area TA2 may have a higher light transmittance than the surrounding area. The camera CA may be disposed under the first transmissive area TA1, and the sensor SN may be disposed under the second transmissive area TA2. Light passed through the first transmissive area TA1 and the second transmissive area TA2 may be provided to the camera CA and the sensor SN.

The display module DM may include a data driver DDV disposed on the peripheral area 100N. The data driver DDV may be manufactured in the form of an integrated circuit chip and may be mounted on the peripheral area 100N. Alternatively, without being limited thereto, the data driver DDV may be mounted on a flexible circuit board connected to the display module DM.

The support part FP may be disposed under the display module DM. The support part FP may support the display module DM. The support part FP may have a plurality of openings H1 defined therein. The plurality of openings H1 may be defined or formed through the support part FP in the third direction DR3. When viewed on a plane or in a plan view in the third direction DR3, the plurality of openings H1 may overlap the first transmissive area TA1 and the second transmissive area TA2, respectively. The camera CA and the sensor SN may be disposed under the plurality of openings H1.

The bracket BRK may be disposed under the support part FP. The bracket BRK may include a first bracket BRK1 and a second bracket BRK2. The first bracket BRK1 and the second bracket BRK2 may extend in the first direction DR1 and may be arranged (or spaced apart from each other) in the second direction DR2. The bracket BRK according to an embodiment of the disclosure may be connected to the support part FP. This configuration will be described below in detail.

The electronic module EM and the power supply module PSM may be disposed under the first and second brackets BRK1 and BRK2. Although not illustrated, the electronic module EM and the power supply module PSM may be connected with each other through a separate flexible circuit board. The electronic module EM may control operation of the display module DM. The power supply module PSM may supply power to the electronic module EM.

The case CAS may accommodate the display module DM, the support part FP, the bracket BRK, the electronic module EM, and the power supply module PSM. In an embodiment where the display module DM is foldable, the case CAS may include a first case CAS1 and a second case CAS2. The first and second cases CAS1 and CAS2 may extend in the first direction DR1 and may be arranged (or spaced apart from each other) in the second direction DR2.

Although not illustrated, the electronic device 1000 may further include a hinge structure for connecting the first and second cases CAS1 and CAS2 and rotating the first and second cases CAS1 and CAS2 to allow the first and second cases CAS1 and CAS2 to be folded. The case CAS may protect the display module DM, the support part FP, the bracket BRK, the electronic module EM, and the power supply module PSM.

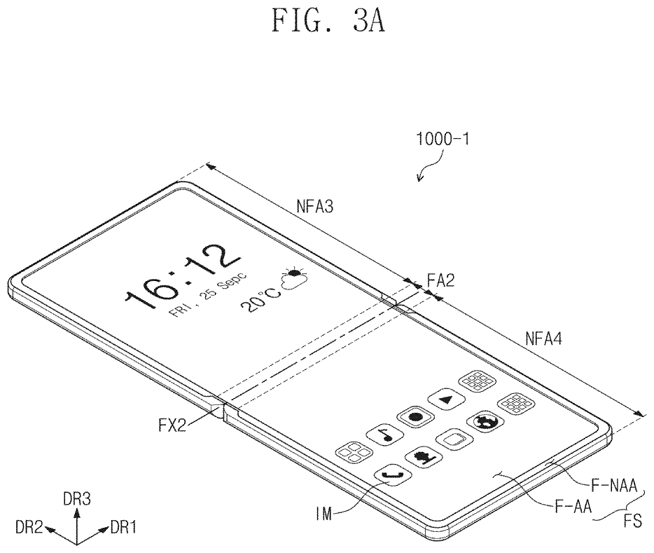

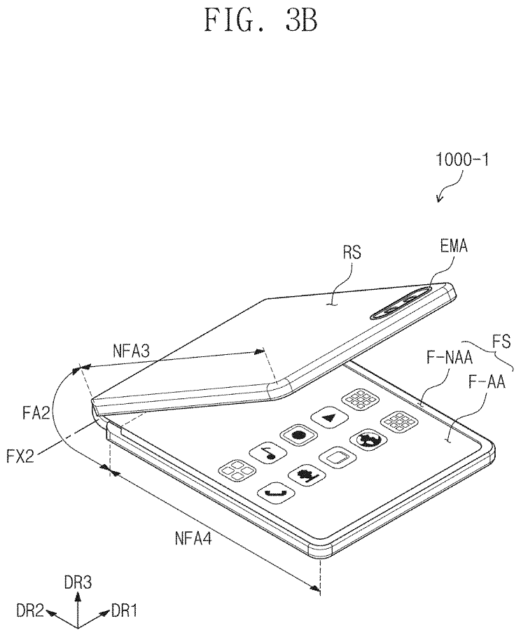

FIG. 3A is a perspective view illustrating an electronic device in a flat state according to an embodiment of the disclosure. FIG. 3B is a perspective view illustrating the electronic device illustrated in FIG. 3A in a folding process. In describing FIGS. 3A and 3B, the same or like components as the components described above with reference to FIGS. 1A to 1D will be assigned with the same or like reference numerals, and any repetitive detailed descriptions thereof will be omitted or simplified.

Referring to FIGS. 3A and 3B, an embodiment of the electronic device 1000-1 may include a first display surface FS and a second display surface RS. The first display surface FS may include a first active area F-AA and a first peripheral area F-NAA. The second display surface RS may be defined as a surface facing away from at least a portion of the first display surface FS. In an in-folded state, the second display surface RS may be visible to a user. The second display surface RS may include an electronic module area EMA in which an electronic module including various components is disposed. In such an embodiment, an image may be provided through the second display surface RS.

The electronic device 1000-1 may include a folding area FA2 and non-folding areas NFA3 and NFA4. The electronic device 1000-1 may include a plurality of non-folding areas NFA3 and NFA4. The plurality of non-folding areas NFA3 and NFA4 may include the first non-folding area NFA3 and the second non-folding area NFA4 disposed with the folding area FA2 therebetween.

The electronic device 1000-1 may be folded about a second folding axis FX2 extending in one direction parallel to the first direction DR1. FIG. 3A illustrates an embodiment where the extension direction of the second folding axis FX2 is parallel to the extension direction of the short sides of the electronic device 1000-1. However, the disclosure is not limited thereto.

The folding area FA2 corresponds to a portion foldable about the second folding axis FX2 parallel to the first direction DR1. The folding area FA2 has a predetermined curvature and a predetermined radius of curvature. In an embodiment, the electronic device 1000-1 may be folded in an in-folding manner such that the first non-folding area NFA3 and the second non-folding area NFA4 face each other and the first display surface FS is not exposed to the outside.

In an alternative embodiment, the electronic device 1000-1 may be folded in an out-folding manner such that the first display surface FS is exposed to the outside. In an embodiment, the first display surface FS may be visible to the user when the electronic device 1000-1 is in an unfolded state, and the second display surface RS may be visible to the user when the electronic device 1000-1 is in an in-folded state. The second display surface RS may include the electronic module area EMA in which an electronic module including various components is disposed.

Various electronic modules may be disposed in the electronic module area EMA. In an embodiment, for example, the electronic modules may include at least one selected from a camera, a speaker, a light detection sensor, and a heat detection sensor. The electronic module area EMA may sense an external object received through the first or second display surface FS or RS, or may provide a sound signal, such as voice, to the outside through the first or second display surface FS or RS. The electronic modules may include a plurality of components and are not limited to any one embodiment.

The electronic module area EMA may be surrounded by the first active area F-AA and the first peripheral area F-NAA. Alternatively, without being limited thereto, the electronic module area EMA may be disposed in the first active area F-AA and is not limited to any one embodiment.

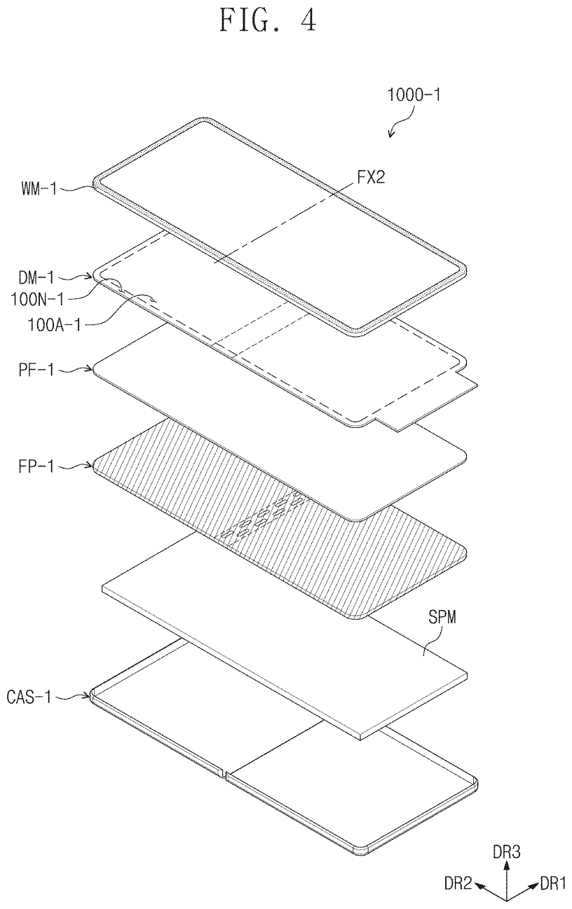

FIG. 4 is an exploded perspective view of the electronic device 1000-1 according to an embodiment of the disclosure. In describing FIG. 4, the same or like components as the components described above with reference to FIG. 2 will be assigned with the same or like reference numerals, and any repetitive detailed descriptions thereof will be omitted or simplified.

Referring to FIG. 4, an embodiment of the electronic device 1000-1 may include a window WM-1, a display module DM-1, a protective layer PF-1, a support part FP-1, a lower member SPM, and a case CAS-1.

The display module DM-1 may have an active area 100A-1 and a peripheral area 100N-1 defined therein. The active area 100A-1 may correspond to the first active area F-AA (refer to FIG. 3A) of the electronic device 1000-1, and the peripheral area 100N-1 may correspond to the first peripheral area F-NAA (refer to FIG. 3A) of the electronic device 1000-1. The expression “one area/portion corresponds to another area/portion” used herein may mean that the areas/portions overlap each other and is not limited to having a same area as each other.

The protective layer PF-1 may be disposed under the display module DM-1. The protective layer PF-1 may be a layer that is disposed under the display module DM-1 and that protects the rear surface of the display module DM-1. The protective layer PF-1 may overlap the entire display module DM-1. The protective layer PF-1 may include a polymer material. In an embodiment, for example, the protective layer PF-1 may be a polyimide film or a polyethylene terephthalate film. However, this is illustrative, and the material of the protective layer PF-1 is not limited thereto.

The support part FP-1 may be disposed under the protective layer PF-1. The support part FP-1 may have substantially the same configuration as the support part FP of FIG. 2.

The lower member SPM may be disposed under the support part FP-1. The lower member SPM may include various components. In an embodiment, for example, the lower member SPM may include an electronic module EM (refer to FIG. 2) and a power supply module PSM (refer to FIG. 2).

The case CAS-1 may accommodate the display module DM-1, the protective layer PF-1, the support part FP-1, and the lower member SPM.

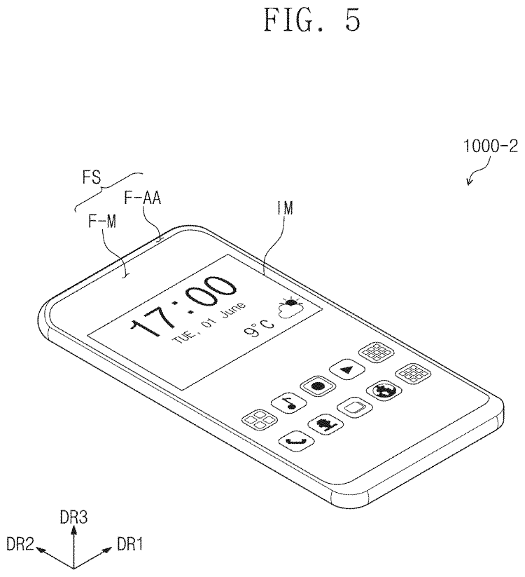

FIG. 5 is a perspective view of an electronic device according to an embodiment of the disclosure. In describing FIG. 5, the same or like components as the components described above with reference to FIGS. 1A to 1D will be assigned with the same or like reference numerals, and any repetitive detailed descriptions thereof will be omitted or simplified.

Referring to FIG. 5, an embodiment of the electronic device 1000-2 may include a first display surface FS. The first display surface FS may include a first active area F-AA and a first peripheral area F-NAA.

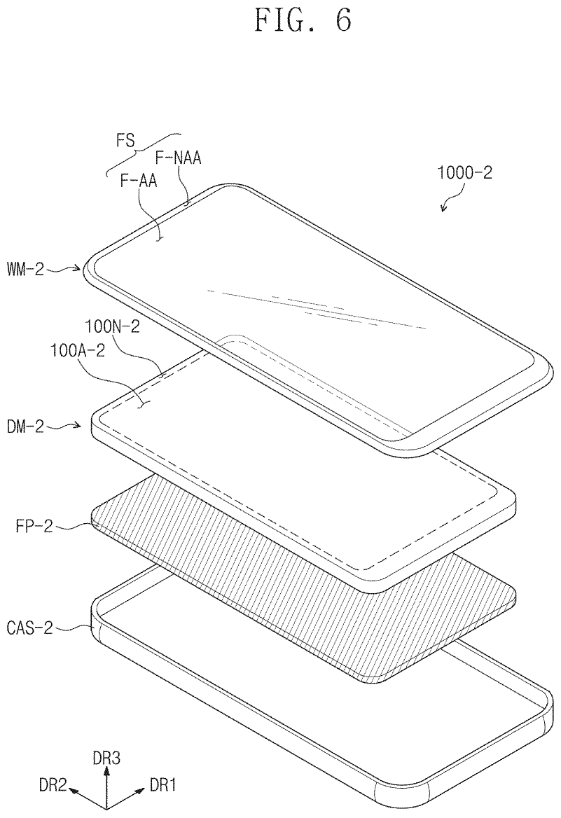

FIG. 6 is an exploded perspective view of the electronic device 1000-2 according to an embodiment of the disclosure. In describing FIG. 6, the same or like components as the components described above with reference to FIG. 2 will be assigned with the same or like reference numerals, and any repetitive detailed descriptions thereof will be omitted or simplified.

Referring to FIG. 6, an embodiment of the electronic device 1000-2 may include a window WM-2, a display module DM-2, a support part FP-2, and a case CAS-2.

The display module DM-2 may have an active area 100A-2 and a peripheral area 100N-2 defined therein. The active area 100A-2 may correspond to the first active area F-AA (refer to FIG. 3A) of the electronic device 1000-2, and the peripheral area 100N-2 may correspond to the first peripheral area F-NAA (refer to FIG. 3A) of the electronic device 1000-2. The expression “one area/portion corresponds to another area/portion” used herein may mean that the areas/portions overlap each other and is not limited to having a same area as each other.

The support part FP-2 may be disposed under the display module DM-2. The support part FP-2 may have substantially the same configuration as the support part FP of FIG. 2.

The case CAS-2 may accommodate the display module DM-2 and the support part FP-2.

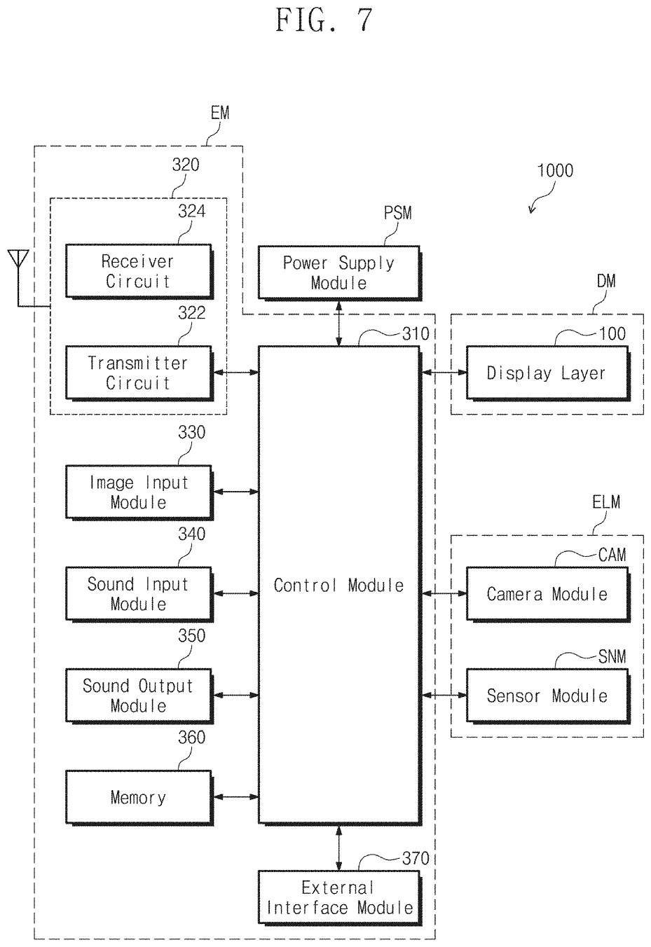

FIG. 7 is a block diagram of the electronic device 1000 according to an embodiment of the disclosure.

Referring to FIG. 7, an embodiment of the electronic device 1000 may include the electronic module EM, the power supply module PSM, the display module DM, and an electro-optical module ELM. The electronic module EM may include a control module 310, a wireless communication module 320, an image input module 330, a sound input module 340, a sound output module 350, memory 360, and an external interface module 370. The modules may be mounted on a circuit board, or may be electrically connected through a flexible circuit board. The electronic module EM may be electrically connected with the power supply module PSM.

The control module 310 may control overall operation of the electronic device 1000. In an embodiment, for example, the control module 310 may activate or deactivate the display module DM in response to a user input. The control module 310 may control the image input module 330, the sound input module 340, and the sound output module 350 in response to a user input. The control module 310 may include at least one microprocessor.

The wireless communication module 320 may transmit/receive wireless signals with another terminal through Bluetooth or Wi-Fi. The wireless communication module 320 may transmit/receive sound signals using a general communication line. The wireless communication module 320 may include a transmitter circuit 322 that modulates a signal to be transmitted and transmits the modulated signal and a receiver circuit 324 that demodulates a received signal.

The image input module 330 may process an image signal to covert the image signal into image data that can be displayed on the display module DM. The sound input module 340 may receive an external sound signal through a microphone in a voice recording mode or a voice recognition mode and may convert the external sound signal into electrical voice data. The sound output module 350 may convert sound data received from the wireless communication module 320 or sound data stored in the memory 360 and may output the converted data to the outside.

The external interface module 370 may serve as an interface connected to an external charger, a wired/wireless data port, a card socket (e.g., a memory card or a SIM/UIM card), or the like.

The power supply module PSM may supply power used for overall operation of the electronic device 1000. The power supply module PSM may include a conventional battery device.

The display module DM may include a display layer 100. The display layer 100 will be described below.

The electro-optical module ELM may be an electronic part that outputs or receives an optical signal. The electro-optical module ELM may transmit or receive an optical signal through a partial area of the display module DM. In an embodiment, the electro-optical module ELM may include a camera module CAM and a sensor module SNM. The camera module CAM may include the camera CA illustrated in FIG. 2. The sensor module SNM may include the sensor SN illustrated in FIG. 2.

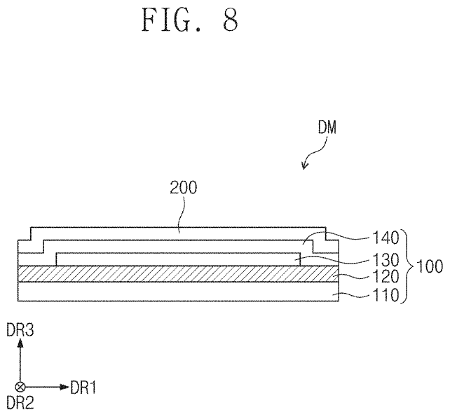

FIG. 8 is a cross-sectional view of the display module DM according to an embodiment of the disclosure.

Referring to FIG. 8, the display module DM may include the display layer 100 and a sensor layer 200. The display layer 100 may include a base layer 110, a circuit layer 120, a light emitting element layer 130, and an encapsulation layer 140.

The base layer 110 may be a member that provides a base surface on which the circuit layer 120 is disposed. The base layer 110 may be a glass substrate, a metal substrate, or a polymer substrate, for example. In an embodiment, without being limited thereto, the base layer 110 may be an inorganic layer, an organic layer, or a composite layer.

The base layer 110 may have a multi-layer structure. In an embodiment, for example, the base layer 110 may include a first synthetic resin layer, a silicon oxide (SiOₓ) layer disposed on the first synthetic resin layer, an amorphous silicon (a-Si) layer disposed on the silicon oxide layer, and a second synthetic resin layer disposed on the amorphous silicon layer. The silicon oxide layer and the amorphous silicon layer may be referred to as the base barrier layer.

Each of the first and second synthetic resin layers may include a polyimide-based resin. Alternatively, each of the first and second synthetic resin layers may include at least one selected from an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, and a perylene-based resin. Here, a “˜˜”-based resin used herein may refer to a resin containing a “˜˜” functional group.

The circuit layer 120 may be disposed on the base layer 110. The circuit layer 120 may include an insulating layer, a semiconductor pattern, a conductive pattern, and a signal line. The insulating layer, a semiconductor layer, and a conductive layer may be formed on the base layer 110 by a process such as coating or deposition and may be selectively subjected to patterning by performing a photolithography process a plurality of times. Thereafter, the semiconductor pattern, the conductive pattern, and the signal line included in the circuit layer 120 may be formed.

The light emitting element layer 130 may be disposed on the circuit layer 120. The light emitting element layer 130 may include light emitting elements. In an embodiment, for example, the light emitting element layer 130 may include an organic light emitting material, quantum dots, quantum rods, a micro-light emitting diode (LED), or a nano-LED.

The encapsulation layer 140 may be disposed on the light emitting element layer 130. The encapsulation layer 140 may protect the light emitting element layer 130 from foreign matter such as moisture, oxygen, and dust particles.

In an embodiment, the sensor layer 200 may be formed on the display layer 100 through a continuous process. In such an embodiment, the sensor layer 200 may be expressed as being directly disposed on the display layer 100. When the sensor layer 200 is directly disposed on the display layer 100, it may mean that a third component is not disposed between the sensor layer 200 and the display layer 100. That is, a separate adhesive member may not be disposed between the sensor layer 200 and the display layer 100. Alternatively, the sensor layer 200 may be coupled with the display layer 100 through an adhesive member. The adhesive member may include a conventional adhesive or sticky substance.

FIG. 9 is a cross-sectional view of the display module DM according to an embodiment of the disclosure. In describing FIG. 9, the same or like components as those described with reference to FIG. 8 will be assigned with the same or like reference numerals, and any repetitive detailed descriptions thereof will be omitted or simplified.

Referring to FIG. 9, at least one inorganic layer may be disposed or formed on the upper surface of the base layer 110. The inorganic layer may include at least one selected from aluminum oxide, titanium oxide, silicon oxide, silicon oxy-nitride, zirconium oxide, and hafnium oxide. The inorganic layer may be formed in multiple layers, that is, have a multi-layer structure. The multiple inorganic layers may include or be defined by a barrier layer and/or a buffer layer. In FIG. 9, an embodiment where the display layer 100 includes a buffer layer BFL is shown.

The buffer layer BFL may improve a bonding force between the base layer 110 and a semiconductor pattern. The buffer layer BFL may include silicon oxide layers and silicon nitride layers, and the silicon oxide layers and the silicon nitride layers may be alternately stacked one on another.

The semiconductor pattern may be disposed on the buffer layer BFL. The semiconductor pattern may include poly-silicon. In such an embodiment, without being limited thereto, the semiconductor pattern may include amorphous silicon, low-temperature polycrystalline silicon, or oxide semiconductor.

FIG. 9 illustrates only a part of semiconductor patterns, and the semiconductor patterns may be additionally disposed in other areas. The semiconductor patterns may be arranged across pixels according to a specific rule. The semiconductor patterns may have different electrical properties depending on whether the semiconductor patterns are doped or not. The semiconductor patterns may include a first area having a high conductivity and a second area having a low conductivity. The first area may be doped with an N-type dopant or a P-type dopant. A P-type transistor may include an area doped with a P-type dopant, and an N-type transistor may include an area doped with an N-type dopant. The second area may be an undoped area, or may be an area more lightly doped than the first area.

The first area may have a higher conductivity than the second area and may substantially serve as an electrode or a signal line. The second area may substantially correspond to an active (or, channel) area of a transistor. In such an embodiment, a portion of the semiconductor pattern may be an active area of a transistor, another portion may be a source or drain of the transistor, and another portion may be a connecting electrode or a connecting signal line.

In an embodiment, each of the pixels may have an equivalent circuit including seven transistors, one capacitor, and a light emitting element, and the equivalent circuit of the pixel may be modified in various forms. In FIG. 9, one transistor 100PC and one light emitting element 100PE that are included in the pixel are illustrated.

The transistor 100PC may include a source S1, an active area A1, a drain D1, and a gate G1. The source S1, the active area A1, and the drain D1 may be formed from the semiconductor pattern. The source S1 and the drain D1 may extend from the active area A1 in opposite directions on the section. In FIG. 9, a portion of a connecting signal line SCL formed from the semiconductor pattern is illustrated. Although not separately illustrated, the connecting signal line SCL may be electrically connected to the drain D1 of the transistor 100PC on the plane.

A first insulating layer 10 may be disposed on the buffer layer BFL. The first insulating layer 10 may commonly overlap a plurality of pixels and may cover the semiconductor pattern. The first insulating layer 10 may be an inorganic layer and/or an organic layer and may have a single-layer structure or a multi-layer structure. The first insulating layer 10 may include at least one selected from aluminum oxide, titanium oxide, silicon oxide, silicon nitride, silicon oxy-nitride, zirconium oxide, and hafnium oxide. In an embodiment, for example, the first insulating layer 10 may be a single layer of silicon oxide. Not only the first insulating layer 10 but also insulating layers of the circuit layer 120 to be described below may be inorganic layers and/or organic layers and may have a single-layer structure or a multi-layer structure. The inorganic layers may include at least one selected from the aforementioned materials, but are not limited thereto.

The gate G1 is disposed on the first insulating layer 10. The gate G1 may be defined by a portion of a metal pattern. The gate G1 overlaps the active area A1. The gate G1 may function as a mask in a process of doping the semiconductor pattern.

A second insulating layer 20 may be disposed on the first insulating layer 10 and may cover the gate G1. The second insulating layer 20 may commonly overlap the pixels. The second insulating layer 20 may be an inorganic layer and/or an organic layer and may have a single-layer structure or a multi-layer structure. The second insulating layer 20 may include at least one selected from silicon oxide, silicon nitride, and silicon oxy-nitride. In an embodiment, for example, the second insulating layer 20 may have a multi-layer structure including a silicon oxide layer and a silicon nitride layer.

A third insulating layer 30 may be disposed on the second insulating layer 20. The third insulating layer 30 may have a single-layer structure or a multi-layer structure. In an embodiment, for example, the third insulating layer 30 may have a multi-layer structure including a silicon oxide layer and a silicon nitride layer.

A first connecting electrode CNE1 may be disposed on the third insulating layer 30. The first connecting electrode CNE1 may be connected to the connecting signal line SCL through a contact hole CNT-1 defined through the first, second, and third insulating layers 10, 20, and 30.

A fourth insulating layer 40 may be disposed on the third insulating layer 30. The fourth insulating layer 40 may be a signal layer of silicon oxide. A fifth insulating layer 50 may be disposed on the fourth insulating layer 40. The fifth insulating layer 50 may be an organic layer.

A second connecting electrode CNE2 may be disposed on the fifth insulating layer 50. The second connecting electrode CNE2 may be connected to the first connecting electrode CNE1 through a contact hole CNT-2 defined through the fourth insulating layer 40 and the fifth insulating layer 50.

A sixth insulating layer 60 may be disposed on the fifth insulating layer 50 and may cover the second connecting electrode CNE2. The sixth insulating layer 60 may be an organic layer.

The light emitting element layer 130 may be disposed on the circuit layer 120. The light emitting element layer 130 may include the light emitting element 100PE. In an embodiment, for example, the light emitting element layer 130 may include an organic light emitting material, quantum dots, quantum rods, a micro-LED, or a nano-LED. Hereinafter, for convenience of description, embodiments where the light emitting element 100PE is an organic light emitting element will be described in detail. However, the light emitting element 100PE is not particularly limited thereto.

The light emitting element 100PE may include a first electrode AE, an emissive layer EL, and a second electrode CE. The first electrode AE may be disposed on the sixth insulating layer 60. The first electrode AE may be connected to the second connecting electrode CNE2 through a contact hole CNT-3 defined through the sixth insulating layer 60.

A pixel defining film 70 may be disposed on the sixth insulating layer 60 and may cover a portion of the first electrode AE. The pixel defining film 70 may have an opening 70-OP defined therein. The opening 70-OP of the pixel defining film 70 exposes at least a portion of the first electrode AE.

The display area 100A (refer to FIG. 2) may include an emissive area PXA and a non-emissive area NPXA adjacent to the emissive area PXA. The non-emissive area NPXA may surround the emissive area PXA. In an embodiment, the emissive area PXA is defined to correspond to a partial area of the first electrode AE exposed through the opening 70-OP.

The emissive layer EL may be disposed on the first electrode AE. The emissive layer EL may be disposed in an area corresponding to the opening 70-OP. In an embodiment, the emissive layer EL may be separately formed for each of the pixels. In such an embodiment where the emissive layer EL is separately formed for each of the pixels, the emissive layers EL may each emit at least one selected from blue light, red light, and green light. In an alternative embodiment, without being limited thereto, the emissive layer EL may be commonly connected to the pixels. In such an embodiment, the emissive layer EL may provide blue light or white light.

The second electrode CE may be disposed on the emissive layer EL. The second electrode CE may have an integral shape and may be commonly disposed for the plurality of pixels.

Although not illustrated, a hole control layer may be disposed between the first electrode AE and the emissive layer EL. The hole control layer may be commonly disposed in the emissive area PXA and the non-emissive area NPXA. The hole control layer may include a hole transporting layer and may further include a hole injection layer. An electron control layer may be disposed between the emissive layer EL and the second electrode CE. The electron control layer may include an electron transporting layer and may further include an electron injection layer. The hole control layer and the electron control layer may be commonly formed for the plurality of pixels by using an open mask.

The encapsulation layer 140 may be disposed on the light emitting element layer 130. The encapsulation layer 140 may include an inorganic layer, an organic layer, and an inorganic layer sequentially stacked one on another. However, layers constituting the encapsulation layer 140 are not limited thereto.

The inorganic layers may protect the light emitting element layer 130 from moisture and oxygen, and the organic layer may protect the light emitting element layer 130 from foreign matter such as dust particles. The inorganic layers may include a silicon nitride layer, a silicon oxy-nitride layer, a silicon oxide layer, a titanium oxide layer, or an aluminum oxide layer. The organic layer may include, but is not limited to, an acrylate-based organic layer.

In an embodiment, the sensor layer 200 may be formed on the display layer 100 through a continuous process. In such an embodiment, the sensor layer 200 may be expressed as being directly disposed on the display layer 100. In such an embodiment where the sensor layer 200 is directly disposed on the display layer 100, it may mean that a third component is not disposed between the sensor layer 200 and the display layer 100. That is, a separate adhesive member may not be disposed between the sensor layer 200 and the display layer 100. Alternatively, the sensor layer 200 may be coupled to the display layer 100 through an adhesive member. The adhesive member may include a conventional adhesive or sticky substance.

The sensor layer 200 may include a base insulating layer 201, a first conductive layer 202, a sensing insulation layer 203, a second conductive layer 204, and a cover insulation layer 205.

The base insulating layer 201 may be an inorganic layer including at least one selected from silicon nitride, silicon oxy-nitride, and silicon oxide. Alternatively, the base insulating layer 201 may be an organic layer including an epoxy resin, an acrylic resin, or an imide-based resin. The base insulating layer 201 may have a single-layer structure, or may have a multi-layer structure stacked in the third direction DR3.

Each of the first conductive layer 202 and the second conductive layer 204 may have a single-layer structure, or may have a multi-layer structure stacked in the third direction DR3.

The conductive layer having the single-layer structure may include a metal layer or a transparent conductive layer. The metal layer may include molybdenum, silver, titanium, copper, aluminum, or an alloy thereof. In an embodiment, the transparent conductive layer may include transparent conductive oxide such as indium tin oxide (ITO), indium zinc oxide (IZO), zinc oxide (ZnO), or indium zinc tin oxide (IZTO). In an embodiment, the transparent conductive layer may include a conductive polymer such as PEDOT, a metal nano wire, or graphene.

The conductive layer having the multi-layer structure may include metal layers. The metal layers may have, for example, a three-layer structure of titanium/aluminum/titanium. The conductive layer having the multi-layer structure may include at least one metal layer and at least one transparent conductive layer.

At least one selected from the sensing insulation layer 203 and the cover insulation layer 205 may include an inorganic film. The inorganic film may include at least one selected from aluminum oxide, titanium oxide, silicon oxide, silicon nitride, silicon oxy-nitride, zirconium oxide, and hafnium oxide.

At least one selected from the sensing insulation layer 203 the cover insulation layer 205 may include an organic film. The organic film may include at least one selected from an acrylate-based resin, a methacrylate-based resin, a polyisoprene-based resin, a vinyl-based resin, an epoxy-based resin, a urethane-based resin, a cellulose-based resin, a siloxane-based resin, a polyimide-based resin, a polyamide-based resin, and a perylene-based resin.

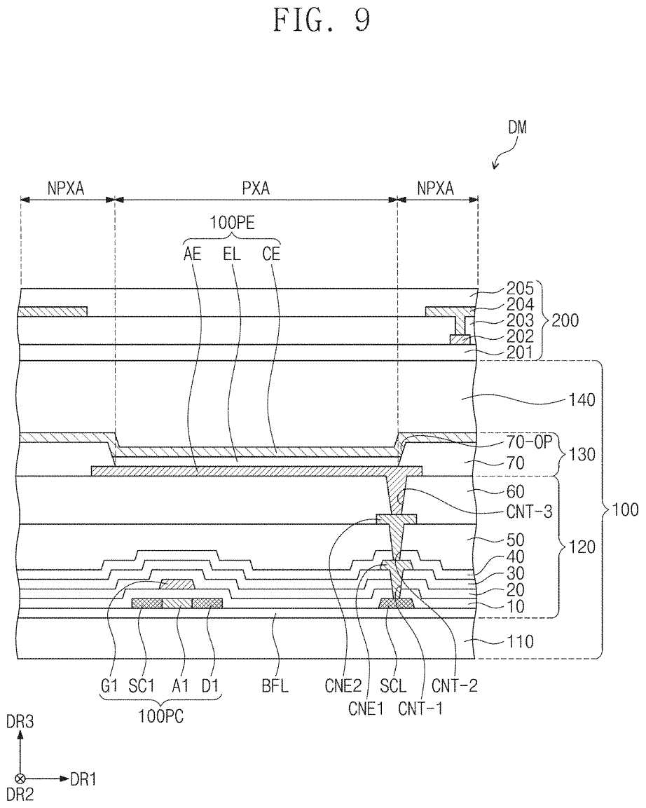

FIG. 10 is a cross-sectional view of the electronic device taken along line I-I′ of FIG. 1A according to an embodiment of the disclosure.

Referring to FIG. 10, an embodiment of the electronic device 1000 may have the first non-folding area NFA1, the folding area FA1, and the second non-folding area NFA2 defined therein. The folding area FA1 may be folded or foldable about the above-described first folding axis FX1 (refer to FIG. 1B).

The folding area FA1 may include a first reverse curvature portion ICV1, a second reverse curvature portion ICV2, and a curved portion CSP. The first reverse curvature portion ICV1 may be disposed between the first non-folding area NFA1 and the curved portion CSP. The second reverse curvature portion ICV2 may be disposed between the second non-folding area NFA2 and the curved portion CSP. The curved portion CSP may be disposed between the first reverse curvature portion ICV1 and the second reverse curvature portion ICV2.

The electronic device 1000 may include the window WM, a shock absorbing layer ISL, the display module DM, a panel protection layer PPL, a barrier layer BRL, the support part FP, a cover layer COV, a digitizer DGT, a shielding layer SHL, a support plate PLT, a plurality of cushion layers CUL disposed between the support plate PLT and the bracket BRK, a plurality of waterproof tapes WTP disposed between the support part FP and the bracket BRK, and first to eighth adhesive layers AL1 to AL8.

When the folding area FA1 is folded, the curved portion CSP may be bent to have a predetermined curvature. The first reverse curvature portion ICV1 and the second reverse curvature portion ICV2 may be bent opposite to the curved portion CSP and may be bent to be symmetrical to each other. The folded state of the folding area FA1 will be described below.

The window WM may include a hard coating layer HC, a window protection layer WP, and a window layer WIN.

The window layer WIN may protect the display layer 100 from external scratches. The window layer WIN may have a property of being optically transparent. In an embodiment, the window layer WIN may include glass. Alternatively, without being limited thereto, the window layer WIN may include a synthetic resin film.

The window layer WIN may have a multi-layer structure or a single-layer structure. In an embodiment, for example, the window layer WIN may include a plurality of synthetic resin films coupled to each other by an adhesive, or may include a glass substrate and a synthetic resin film coupled to each other by an adhesive.

The window protection layer WP may be disposed over the window layer WIN. The window protection layer WP may include a flexible plastic material such as polyimide or polyethylene terephthalate. The hard coating layer HC may be disposed on the upper surface of the window protection layer WP.

A printed layer PIT may be disposed on the lower surface of the window protection layer WP. The printed layer PIT may be black in color, but the color of the printed layer PIT is not limited thereto. The printed layer PIT may be adjacent to the periphery of the window protection layer WP.

The first adhesive layer AL1 may be disposed between the window protection layer WP and the window layer WIN. The window protection layer WP and the window WIN may be bonded to each other by the first adhesive layer AL1. The first adhesive layer AL1 may cover the printed layer PIT.

The shock absorbing layer ISL may be disposed over the display module DM. The shock absorbing layer ISL may protect the display module DM by absorbing external shock applied toward the display module DM from above the electronic device 1000. The shock absorbing layer ISL may be manufactured in the form of a stretchable film.

The shock absorbing layer ISL may include a flexible plastic material. The flexible plastic material may be defined as a synthetic resin film. In an embodiment, for example, the shock absorbing layer ISL may include a flexible plastic material such as polyimide (PI) or polyethylene terephthalate (PET).

The second adhesive layer AL2 may be disposed between the window layer WIN and the shock absorbing layer ISL. The window layer WIN and the shock absorbing layer ISL may be bonded to each other by the second adhesive layer AL2.

The display module DM may be a flexible display module. The display module DM may include the display layer 100 and the sensor layer 200.

The display layer 100 may have a first area AR1, a second area AR2, and a third area AR3 defined therein. The second area AR2 may be spaced apart from the first area AR1 in the second direction DR2, and the third area AR3 may be spaced apart from the first area AR1 in the second direction DR2 with the second area AR2 therebetween.

When viewed on the plane, the first area AR1 may overlap the first non-folding area NFA1. The second area AR2 may overlap the folding area FA1. The third area AR3 may overlap the second non-folding area NFA2.

The third adhesive layer AL3 may be disposed between the shock absorbing layer ISL and the display module DM. The shock absorbing layer ISL and the display module DM may be bonded to each other by the third adhesive layer AL3.

The panel protection layer PPL may protect the bottom of the display module DM. The panel protection layer PPL may include a flexible plastic material. In an embodiment, for example, the panel protection layer PPL may include polyethylene terephthalate (PET).

The fourth adhesive layer AL4 may be disposed between the display module DM and the panel protection layer PPL. The display module DM and the panel protection layer PPL may be bonded to each other by the fourth adhesive layer AL4.

The barrier layer BRL may be disposed under the panel protection layer PPL. The barrier layer BRL may increase resistance to a compressive force caused by external pressing. Accordingly, the barrier layer BRL may serve to prevent deformation of the display module DM. The barrier layer BRL may include a flexible plastic material such as polyimide or polyethylene terephthalate.

The barrier layer BRL may have a color that absorbs light. In an embodiment, for example, the barrier layer BRL may be black in color. In such an embodiment, components disposed under the barrier layer BRL may not be visible when the display module DM is viewed from above the display module DM.

The fifth adhesive layer AL5 may be disposed between the panel protection layer PPL and the barrier layer BRL. The panel protection layer PPL and the barrier layer BRL may be bonded to each other by the fifth adhesive layer AL5.

The sixth adhesive layer AL6 may be disposed between the barrier layer BRL and the support part FP. The barrier layer BRL and the support part FP may be bonded to each other by the sixth adhesive layer AL6.

The sixth adhesive layer AL6 may overlap the first and second non-folding areas NFA1 and NFA2 and may not overlap the curved portion CSP of the folding area FA 1 when viewed on the plane. That is, the sixth adhesive layer AL6 may not be disposed in the curved portion CSP.

The first to sixth adhesive layers AL1 to AL6 may include a transparent adhesive such as a pressure sensitive adhesive (PSA) or an optically clear adhesive (OCA), but are not limited thereto.

The support part FP may be disposed under the barrier layer BRL. The support part FP may have a greater stiffness than the display module DM. The support part FP may be disposed under the display module DM and may support the display module DM.

The support part FP may be disposed under the first area AR1, the second area AR2, and the third area AR3. The support part FP may have a continuous integral shape.

The support part FP may be disposed under the display layer 100 and may support the display layer 100. The support part FP may include a non-metallic material. In an embodiment, for example, the support part FP may include a fiber reinforced composite. In an embodiment, for example, the support part FP may include carbon fiber reinforced plastic (CFRP) or glass fiber reinforced plastic (GFRP). The support part FP will be described later in greater detail.

The support part FP including the fiber reinforced composite may be relatively light. Compared to a conventional metal support part including a metallic material, the support part FP including the fiber reinforced composite may be light in weight and may have modulus and strength similar to those of the metal support part.

The support part FP including the fiber reinforced composite may be more easily shaped than the metal support part. In an embodiment, for example, the support part FP including the fiber reinforced composite may be more easily shaped through a laser process or a micro-blast process.

A plurality of pattern holes OP may be defined in a portion of the support part FP that overlaps the folding area FA1 when viewed on the plane. The plurality of pattern holes OP may overlap the curved portion CSP when viewed on the plane. The plurality of pattern holes OP may overlap the second area AR2 when viewed on the plane. The plurality of pattern holes OP may be defined or formed through portions of the support part FP in the third direction DR3. The plurality of pattern holes OP may be formed through the laser process or the micro-blast process mentioned above.

The plurality of pattern holes OP may be defined in a portion of the support part FP that overlaps the curved portion CSP, and thus the flexibility of the portion of the support part FP that overlaps the curved portion CSP may be improved. Accordingly, the support part FP may be easily folded with respect to the folding area FA1.

The cover layer COV may be disposed under the support part FP. The cover layer COV under the support part FP may cover the plurality of pattern holes OP defined in the support part FP. The cover layer COV, when viewed on the plane, may overlap the folding area FA1 and may not overlap the first and second non-folding areas NFA1 and NFA2. The cover layer COV may contact the lower surface of the portion of the support part FP that has the plurality of pattern holes OP formed therein.

The cover layer COV may have a lower elastic modulus than the support part FP. In an embodiment, for example, the cover layer COV may include thermoplastic polyurethane or rubber. However, the disclosure is not limited thereto. The cover layer COV may be manufactured in a sheet form and may be attached to the support part FP.

The digitizer DGT may be disposed under the support part FP. The cover layer COV may be disposed between the support part FP and the digitizer DGT. The cover layer COV may be spaced apart from the upper surface of the digitizer DGT.

The digitizer DGT may receive an input of position information that a user instructs on the display surface. The digitizer DGT may be implemented in an electromagnetic type (or, an electromagnetic resonance type). In an embodiment, for example, the digitizer DGT may include a digitizer sensor substrate including a plurality of coils. However, without being limited thereto, the digitizer DGT may be implemented in an active electrostatic type.

When the user moves a pen on the electronic device 1000, the pen may be driven by an AC signal to cause an oscillating magnetic field, and the oscillating magnetic field may induce a signal to the coils. The position of the pen may be detected through the signal induced to the coils. The digitizer DGT may recognize the position of the pen by sensing an electromagnetic change caused by access of the pen.

If the support part FP disposed over the digitizer DGT and adjacent to the digitizer DGT includes metal, the sensitivity of the digitizer DGT may be lowered by the metal. For example, when a signal transmitted on the electronic device 1000 is blocked due to signal interference by the metal support plate, the digitizer DGT may not normally operate. However, in an embodiment of the disclosure, the support part FP disposed over the digitizer DGT may include the non-metallic fiber reinforced composite, and thus the digitizer DGT may normally operate.

The digitizer DGT may be divided into two parts under the folding area FA1. Although not illustrated, the separated parts of the digitizer DGT may be connected to a digitizer driver (not illustrated) through flexible circuit boards. Alternatively, the digitizer DGT may be omitted.

The shielding layer SHL may be disposed under the digitizer DGT. The digitizer DGT may be disposed between the support part FP and the shielding layer SHL. The shielding layer SHL may include metal. In an embodiment, for example, the shielding layer SHL may include copper, but is not limited thereto. The shielding layer SHL may be divided into two parts under the folding area FA1. The separated parts of the shielding layer SHL may be disposed under the separated parts of the digitizer DGT, respectively.

The seventh adhesive layer AL7 may be disposed between the support part FP and the digitizer DGT. The support part FP and the digitizer DGT may be bonded to each other by the seventh adhesive layer AL7.

The seventh adhesive layer AL7 may be open in the portion overlapping the curved portion CSP such that the seventh adhesive layer AL7 is not disposed under the curved portion CSP. The cover layer COV may be disposed in the opening of the seventh adhesive layer AL7.

The shielding layer SHL may shield electromagnetism that is applied to the digitizer DGT from below the electronic device 1000. The shielding layer SHL may be defined as an electromagnetic shielding layer. The shielding layer SHL including the metal may serve as a heat radiating layer.

The support plate PLT may be disposed under the shielding layer SHL. The shielding layer SHL and the digitizer DGT may be disposed between the support part FP and the support plate PLT.

The support plate PLT may include a metallic material such as stainless steel (e.g., SUS 316). Alternatively, without being limited thereto, the support plate PLT may include a non-metallic material such as plastic.

The support plate PLT may be divided into two parts in the folding area FA1. The support plate PLT, when viewed on the plane, may include a first support plate PLT-1 overlapping the first non-folding area NFA1 and a second support plate PLT-2 overlapping the second non-folding area NFA2. The first support plate PLT-1 and the second support plate PLT-2 may be spaced apart from each other in the horizontal direction (e.g., the second direction DR2).

The first support plate PLT-1 may support the first non-folding area NFA1. The second support plate PLT-2 may support the second non-folding area NFA2. The first support plate PLT-1 and the second support plate PLT-2 may extend below the folding area FA1 and may be spaced apart from each other. In an embodiment, the first support plate PLT-1 and the second support plate PLT-2 may extend below the curved portion CSP and may be spaced apart from each other.

The first support plate PLT-1 and the second support plate PLT-2 under the folding area FA1 may support the portion of the support part FP in which the plurality of pattern holes OP is defined. When pressure is applied to the support part FP from above, the first support plate PLT-1 and the second support plate PLT-2 may prevent deformation of the portion of the support part FP that has the plurality of pattern holes OP defined therein. In an embodiment, the first and second support plates PLT-1 and PLT-2 may perform a heat radiating function.

The eighth adhesive layer AL8 may be disposed between the shielding layer SHL and the support plate PLT. The shielding layer SHL and the support plate PLT may be bonded to each other by the eighth adhesive layer AL8. The eighth adhesive layer AL8 may be divided into two parts under the folding area FA1. The separated parts of the eighth adhesive layer AL8 may be disposed between the separated parts of the shielding layer SHL and the first and second support plates PLT-1 and PLT-2.

The seventh and eighth adhesive layers AL7 and AL8 may include a pressure sensitive adhesive (PSA) or an optically clear adhesive (OCA), but are not limited thereto.

The bracket BRK, the cushion layers CUL, and the waterproof tapes WTP may be disposed under the first and second support plates PLT-1 and PLT-2. The bracket BRK may include a first bracket BRK1 disposed under the first support plate PLT-1 and a second bracket BRK2 disposed under the second support plate PLT-2. The first bracket BRK1 and the second bracket BRK2 may be disposed under the separated parts of the digitizer DGT, respectively. The first bracket BRK1 and the second bracket BRK2 may be spaced apart from each other in the horizontal direction (e.g., the second direction DR2).

The first support plate PLT-1 may be disposed between the support part FP and the first bracket BRK1. The second support plate PLT-2 may be disposed between the support part FP and the second bracket BRK2. When viewed on the plane, the first bracket BRK1 may overlap the first non-folding area NFA1, and the second bracket BRK2 may overlap the second non-folding area NFA2.

A first groove GV1 may be defined on the upper surface of the portion of the first bracket BRK1 that faces the first support plate PLT-1. A second groove GV2 may be defined on the upper surface of the portion of the second bracket BRK2 that faces the second support plate PLT-2.

The first groove GV1 may be defined on the upper surface of the portion of the first bracket BRK1 that is adjacent to the second bracket BRK2. The first groove GV1 may be defined from one side OS1 of the first bracket BRK1 that faces the second bracket BRK2.

The second groove GV2 may be defined on the upper surface of the portion of the second bracket BRK2 that is adjacent to the first bracket BRK1. The second groove GV2 may be defined from one side OS2 of the second bracket BRK2 that faces the first bracket BRK1.

The cushion layers CUL may be disposed between the first and second support plates PLT-1 and PLT-2 and the first and second brackets BRK1 and BRK2. The cushion layers CUL may be disposed in the first and second grooves GV1 and GV2.

The cushion layers CUL may absorb external shock applied to a lower portion of the display module DM. The cushion layers CUL may include a foam sheet having a predetermined elasticity. The cushion layers CUL may include expanded foam, a sponge, poly-urethane, or thermoplastic poly-urethane.

The cushion layers CUL may include a plurality of first cushion layers CUL1 and a plurality of second cushion layers CUL2. The first cushion layers CUL1 may be disposed adjacent to the one side OS1 of the first bracket BRK1 and the one side OS2 of the second bracket BRK2 that face each other.

The border between the upper surface US1 of the first bracket BRK1 on which the first groove GV1 is not defined and the first groove GV1 may be defined as the first border BA1. The border between the upper surface US2 of the second bracket BRK2 on which the second groove GV2 is not defined and the second groove GV2 may be defined as the second border BA2. The height difference HT between the first and second grooves GV1 and GV2 and the upper surfaces US1 and US2 based on the third direction DR3 may be set to be in a range of about 0.2 millimeter (mm) to about 0.7 mm. In an embodiment, for example, the height difference HT may be set to be about 0.35 mm.

The second cushion layers CUL2 may be spaced apart from the first cushion layers CUL1 and may be disposed adjacent to the first and second borders BA1 and BA2. The second cushion layers CUL2 may be disposed to make contact with a first side surface SS1 of the first bracket BRK1 formed at the first border BA1 and a second side surface SS2 of the second bracket BRK2 formed at the second border BA2.

A first opening OP1 may be defined in the portion of the first support plate PLT-1 that overlaps the first border BA1 when viewed on the plane. A second opening OP2 may be defined in the portion of the second support plate PLT-2 that overlaps the second border BA2 when viewed on the plane.

When viewed on the plane, the first opening OP1 may overlap the first reverse curvature portion ICV1, and the second opening OP2 may overlap the second reverse curvature portion ICV2. When viewed on the plane, the first opening OP1 may overlap the portion of the first reverse curvature portion ICV1 that is adjacent to the first non-folding area NFA1, and the second opening OP2 may overlap the portion of the second reverse curvature portion ICV2 that is adjacent to the second non-folding area NFA2.

In an embodiment, the first and second cushion layers CUL1 and CUL2 may be attached to the first and second brackets BRK1 and BRK2 and may not be attached to the first and second support plates PLT-1 and PLT-2. Alternatively, without being limited thereto, the first and second cushion layers CUL1 and CUL2 may not be attached to the first and second brackets BRK1 and BRK2 and may be attached to the first and second support plates PLT-1 and PLT-2.

The waterproof tapes WTP may be disposed between the first and second support plates PLT-1 and PLT-2 and the first and second brackets BRK1 and BRK2. The waterproof tapes WTP may be attached to the first and second support plates PLT-1 and PLT-2 and the first and second brackets BRK1 and BRK2.

The waterproof tapes WTP may be disposed adjacent to the peripheries of the first and second brackets BRK1 and BRK2. The peripheries of the first and second brackets BRK1 and BRK2 may face toward the outside of the electronic device 1000. In an embodiment, for example, the peripheries of the first and second brackets BRK1 and BRK2 may be defined as side surfaces of the first and second brackets BRK1 and BRK2 that are disposed to face toward the outside of the electronic device 1000 and that do not face each other.

The lower portions of the waterproof tapes WTP may be disposed in recesses RES defined on portions of the upper surfaces of the first and second brackets BRK1 and BRK2. Accordingly, the waterproof tapes WTP may be more firmly fixed to the first and second brackets BRK1 and BRK2.

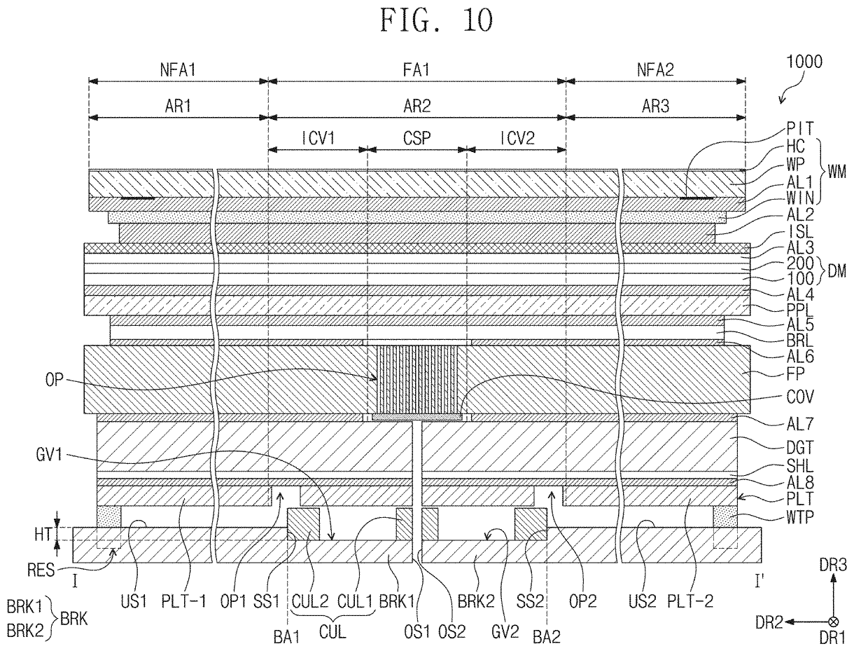

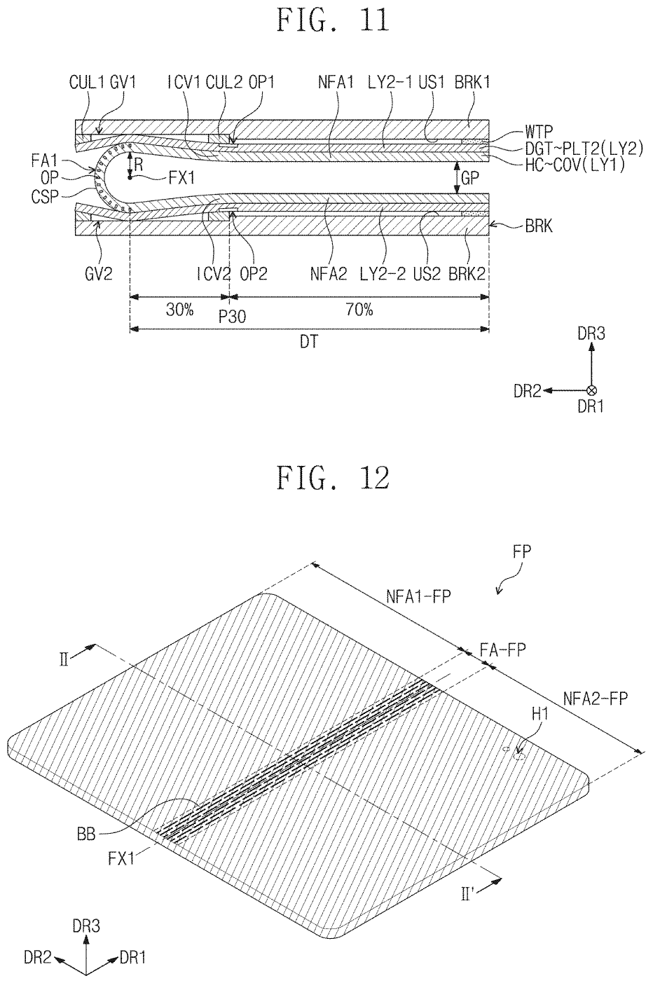

FIG. 11 is a cross-sectional view illustrating a folded state of the electronic device 1000 according to an embodiment of the disclosure. In describing FIG. 11, the same or like components as those described above with reference to FIG. 10 will be assigned with the same or like reference numerals, and any repetitive detailed descriptions thereof will be omitted or simplified.

In FIG. 11, for convenience of illustration, the layers from the hard coating layer HC to the cover layer COV are illustrated as a single layer, and hereinafter, the single layer will be referred to as the first layer LY1. In FIG. 11, for convenience of illustration, the layers from the digitizer DGT to the support plate PLT are illustrated as a single layer, and hereinafter, the single layer will be referred to as the second layer LY2.

Referring to FIG. 11, an embodiment of the electronic device 1000 may be folded about the first folding axis FX1 in an in-folding manner. The folding area FA1 may be bent, and thus the first non-folding area NFA1 and the second non-folding area NFA2 may face each other. The electronic device 1000 may be changed from the first state (the flat state) illustrated in FIG. 10 to the second state (the folded state) illustrated in FIG. 11, or may be changed from the second state to the first state. Such a folding motion may be repeatedly performed.

In the folding motion of the electronic device 1000, a portion of the support part FP that overlaps the folding area FA1 may be easily bent by the plurality of pattern holes OP defined in the support part FP.

In the folding motion of the electronic device 1000, the curved portion CSP may be bent about the first folding axis FX1 to have a predetermined radius of curvature R. The first reverse curvature portion ICV1 may be bent opposite to the curved portion CSP. The second reverse curvature portion ICV2 may be bent opposite to the curved portion CSP. The first reverse curvature portion ICV1 and the second reverse curvature portion ICV2 may be bent to be symmetrical to each other.

In an embodiment, for example, the first layer LY1 may be folded in a dumbbell shape. Accordingly, the distance between the first non-folding area NFA1 and the second non-folding area NFA2 may be smaller than the diameter of a circle having the radius of curvature R.

The second layer LY2 may include a first second layer (hereinafter, will be referred to as “layer 2-1”) LY2-1 and a second second layer (hereinafter, will be referred to as “layer 2-2”) LY2-2 separated under the folding area FA1. The layer 2-1 LY2-1 may be bent to be convex upward in the space between the first cushion layer CUL1 and the second cushion layer CUL2 that are disposed in the first groove GV1. The layer 2-1 LY2-1 may be bent to be convex downward over the first reverse curvature portion ICV1 adjacent to the first non-folding area NFA1.

The layer 2-1 LY2-1 may be more easily bent to be convex upward by the space defined between the first cushion layer CUL1 and the second cushion layer CUL2 in the first groove GV1. As the first opening OP1 is defined in the layer 2-1 LY2-1, the layer 2-1 LY2-1 may be more easily bent to be convex downward over the first reverse curvature portion ICV1.

The layer 2-2 LY2-2 may be bent to be convex downward in the space between the first cushion layer CUL1 and the second cushion layer CUL2 that are disposed in the second groove GV2. The layer 2-2 LY2-2 may be bent to be convex upward under the second reverse curvature portion ICV2 adjacent to the second non-folding area NFA2.

The layer 2-2 LY2-2 may be more easily bent to be convex downward by the space defined between the first cushion layer CUL1 and the second cushion layer CUL2 in the second groove GV2. As the second opening OP2 is defined in the layer 2-2 LY2-2, the layer 2-2 LY2-2 may be more easily bent to be convex upward under the first reverse curvature portion ICV1.

The layer 2-1 LY2-1 and the layer 2-2 LY2-2 may extend flat along the upper surfaces US1 and US2 of the first and second brackets BRK1 and BRK2 on which the first and second grooves GV1 and GV2 are not formed.

The second layer LY2 may guide a folded state of the first layer LY1. As the second layer LY2 is bent to have the above-described shape, the first layer LY1 may be more easily bent along the second layer LY2 to have a dumbbell shape. In an embodiment where the first layer LY1 is folded in a dumbbell shape, the distance between the first and second non-folding areas NFA1 and NFA2 may be further decreased. Accordingly, in such an embodiment of the disclosure, the display module DM may be more easily folded in a dumbbell shape.

In an embodiment, for example, the radius of curvature R may be set to about 2 mm. The gap GP between the first and second non-folding areas NFA1 and NFA2 may be smaller than about 2 mm. In an embodiment, for example, the gap GP between the first and second non-folding areas NFA1 and NFA2 may be set to about 1.5 mm.

The distance DT from the borders between the curved portion CSP and the first and second reverse curvature portions ICV1 and ICV2 to the ends of the first and second non-folding areas NFA1 and NFA2 may be defined as the distance measured in the second direction DR2. The central portions of the first and second openings OP1 and OP2 may be disposed at points P30 that correspond to about 30% of the distance DT from the borders between the curved portion CSP and the first and second reverse curvature portions ICV1 and ICV2.

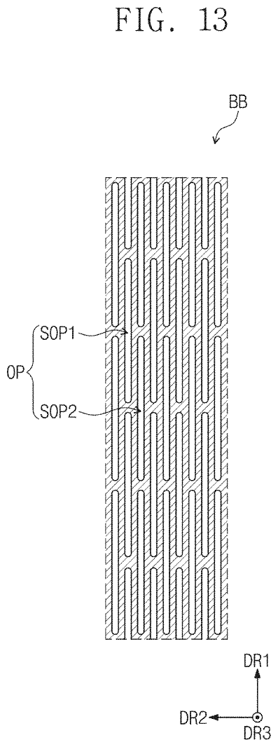

FIG. 12 is a perspective view illustrating the support part FP according to an embodiment of the disclosure, and FIG. 13 is a plan view illustrating an area BB of FIG. 12 according to an embodiment of the disclosure.

Referring to FIGS. 10, 12, and 13, in an embodiment, the support part FP may include a folding portion FA-FP and non-folding portions NFA1-FP and NFA2-FP. The first non-folding portion NFA1-FP and the second non-folding portion NFA2-FP may be spaced apart from each other in the second direction DR2 with the folding portion FA-FP therebetween.

The folding portion FA-FP may be a portion corresponding to the folding area FA1. The non-folding portions NFA1-FP and NFA2-FP may be portions corresponding to the non-folding areas NFA1 and NFA2.

The folding portion FA-FP may have the plurality of pattern holes OP defined therein. However, this is illustrative, and in an alternative embodiment where a foldable configuration is defined as in the support part FP-2 shown in FIG. 6, the plurality of pattern holes OP may be omitted in the support part FP-2 (refer to FIG. 6).

The plurality of pattern holes OP may be arranged to be spaced apart from each other in the first direction DR1 and the second direction DR2. In an embodiment, the plurality of pattern holes OP may extend longer in the first direction DR1 than in the second direction DR2. In such an embodiment, the plurality of pattern holes OP may extend in a direction parallel to the first folding axis FX1.

The plurality of pattern holes OP may include a plurality of first sub-pattern holes SOP1 arranged in the first direction DR1 and a plurality of second sub-pattern holes SOP2 arranged in the first direction DR1 to be adjacent to the plurality of first sub-pattern holes SOP1 in the second direction DR2. The plurality of first sub-pattern holes SOP1 and the plurality of second sub-pattern holes SOP2 may be alternately disposed.

The second non-folding portion NFA2-FP may have the plurality of openings H1 defined therein. When viewed on the plane, the plurality of openings H1 may overlap the first transmissive area TA1 (refer to FIG. 2) and the second transmissive area TA2 (refer to FIG. 2), respectively, such that the light transmittances of the first transmissive area TA1 (refer to FIG. 2) and the second transmissive area TA2 (refer to FIG. 2) may be improved.

The support part FP may include at least one fiber reinforced composite. In an embodiment, for example, the support part FP may include carbon fiber reinforced plastic (CFRP) or glass fiber reinforced plastic (GFRP).

FIG. 14 is a cross-sectional view taken along line II-II′ of FIG. 12 according to an embodiment of the disclosure. In describing FIG. 14, the same or like components as those described above with reference to FIG. 12 will be assigned with the same or like reference numerals, and any repetitive detailed descriptions thereof will be omitted or simplified.

Referring to FIG. 14, the support part FP may have a thickness H-FP in the third direction DR3. The thickness H-FP of the support part FP may be in a range from about 140 micrometers (μm) to about 150 μm. In an embodiment, for example, the thickness H-FP of the support part FP may be about 148.020 μm. The support part FP may include a first support portion F1, a second support portion F2, and a third support portion F3.

The first support portion F1 may have a first surface S1 and a second surface S2 defined thereon, and the second surface S2 may be opposite to the first surface S1. The first support portion F1 may include a first material. The first material may include glass fiber reinforced plastic (GFRP). The first surface S1 may face the display layer 100 (refer to FIG. 10). The first support portion F1 may be closer to the display layer 100 (refer to FIG. 10) than the second support portion F2. The first support portion F1 may have a first thickness H1. The first thickness H1 may be in a range from about 25 μm to about 35 μm. In an embodiment, for example, the first thickness H1 may be about 29.703 μm.

The second support portion F2 may face the second surface S2 of the first support portion F1. The second support portion F2 may make contact with the first support portion F1. That is, the second surface S2 of the first support portion F1 may make contact with a first surface S1-1 of the second support portion F2. The second support portion F2 may include a second material different from the first material. The second material may include carbon fiber reinforced plastic (CFRP). The second support portion F2 may have a second thickness H2. The second thickness H2 may be greater than the first thickness H1. The second thickness H2 may be in a range from about 75 μm to about 85 μm. In an embodiment, for example, the second thickness H2 may be about 79.208 μm.

The third support portion F3 may be disposed under the second support portion F2. The third support portion F3 may be spaced apart from the first support portion F1 with the second support portion F2 therebetween. The third support portion F3 may include the first material. The third support portion F3 may have a third thickness H3. The third thickness H3 may be smaller than the second thickness H2 and greater than the first thickness H1. The third thickness H3 may be in a range from about 30 μm to about 40 μm. In an embodiment, for example, the third thickness H3 may be about 36.634 μm.

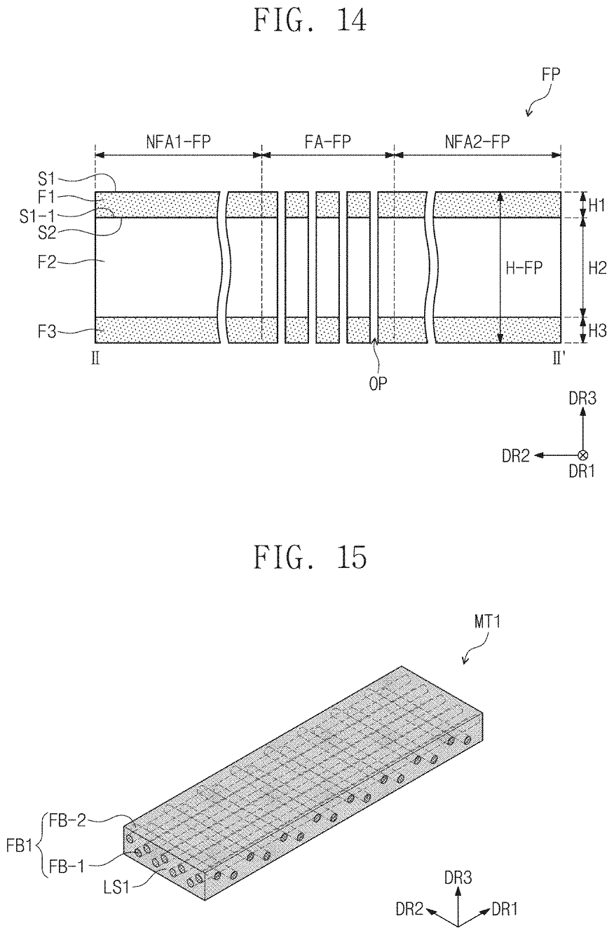

FIG. 15 is a view illustrating the first material of the support part according to an embodiment of the disclosure.

Referring to FIGS. 14 and 15, the first support portion F1 facing the display layer 100 (refer to FIG. 10) and the third support portion F3 disposed under the second support portion F2 may each include the first material MT1. The first material MT1 may include glass fiber reinforced plastic (GFRP). The support part FP including the fiber reinforced composite may be substantially light. The support part FP including the fiber reinforced composite may be lighter in weight than a conventional support part including a metallic material and may have modulus and strength similar to those of a metal plate. Accordingly, an embodiment of the electronic device 1000 (refer to FIG. 10) may be light in weight and may exhibit high mechanical properties and reliability, as compared with a conventional electronic device including a metal support plate.

The glass fiber reinforced plastic may include a first resin LS1 and glass fibers FB1.

The first resin LS1 may include a polymer resin. The first resin LS1 may include a thermoplastic resin. In an embodiment, for example, the first resin LS1 may include a polyamide-based resin or a polypropylene-based resin. The first resin LS1 may be referred to as the first matrix.

The support part FP including the polymer resin as the first resin LS1 may be more easily shaped than a metal plate. In an embodiment, for example, the support part FP including the fiber reinforced composite may be shaped by using laser cutting. The plurality of pattern holes OP may be easily defined in the support part FP by using a laser cutting method.

The glass fibers FB1 may be disposed inside the first resin LS1. The glass fibers FB1 may include glass. The glass fibers FB1 may have a relatively high density and may be relatively heavy in weight, compared to carbon fibers. Furthermore, the glass fibers FB1 may be manufactured at a relatively low cost. The glass fibers FB1 may include a first fiber FB-1 and a second fiber FB-2.

The first fiber FB-1 may extend in the first direction DR1. A plurality of first fibers FB-1 may be provided. The plurality of first fibers FB-1 may be arranged in the second direction DR2 to be spaced apart from each other.

The second fiber FB-2 may be spaced apart from the first fiber FB-1 in the third direction DR3. The second fiber FB-2 may extend in the second direction DR2. A plurality of second fibers FB-2 may be provided. The plurality of second fibers FB-2 may be arranged in the first direction DR1 to be spaced apart from each other.

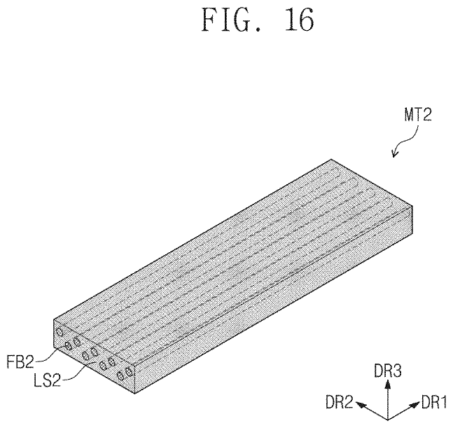

FIG. 16 is a view illustrating the second material of the support part according to an embodiment of the disclosure.

Referring to FIGS. 14 and 16, the second support portion F2 spaced apart from the display layer 100 (refer to FIG. 10) with the first support portion F1 therebetween may include the second material MT2. The second material MT2 may include carbon fiber reinforced plastic (CFRP). The support part FP including the fiber reinforced composite may be substantially light. The support part FP including the fiber reinforced composite may be lighter in weight than a conventional support part including a metallic material and may have modulus and strength similar to those of a metal plate. Accordingly, an embodiment of the electronic device 1000 (refer to FIG. 10) may be light in weight and may exhibit high mechanical properties and reliability, as compared with a conventional electronic device including a metal support plate.

The carbon fiber reinforced plastic may include a second resin LS2 and a carbon fiber FB2.

The second resin LS2 may include a polymer resin. The second resin LS2 may include a thermoplastic resin. In an embodiment, for example, the second resin LS2 may include a polyamide-based resin or a polypropylene-based resin. The second resin LS2 may be referred to as the second matrix.

The support part FP including the polymer resin as the second resin LS2 may be more easily shaped than a metal plate. In an embodiment, for example, the support part FP including the fiber reinforced composite may be shaped by using laser cutting. The plurality of pattern holes OP may be easily defined in the support part FP by using a laser cutting method.

The carbon fiber FB2 may be disposed inside the second resin LS2. The carbon fiber FB2 may include carbon. The carbon fiber FB2 may be relatively light in weight and may have a relatively low density, compared to a glass fiber. Furthermore, the carbon fiber FB2 may be manufactured at a relatively high cost. The carbon fiber FB2 may extend in the first direction DR1. A plurality of carbon fibers FB2 may be provided. The plurality of carbon fibers FB2 may be arranged in the second direction DR2 to be spaced apart from each other.

In a case where a support part includes only carbon fiber reinforced plastic (CFRP) unlike in an embodiment of the disclosure, the manufacturing cost of the support part may be increased. For example, the manufacturing cost of carbon fiber reinforced plastic may be about 5 times to about 25 times higher than the manufacturing cost of glass fiber reinforced plastic. In another case where a support part includes only glass fiber reinforced plastic (GFRP), the weight of the support part may be increased, and therefore the weight of an electronic device may be increased. According to embodiments of the disclosure, the support part FP may include both carbon fiber reinforced plastic and glass fiber reinforced plastic. In such embodiments, the support part FP may be manufactured at a relatively low cost and may be light in weight. Accordingly, the electronic device 1000 (refer to FIG. 10) may be made light.

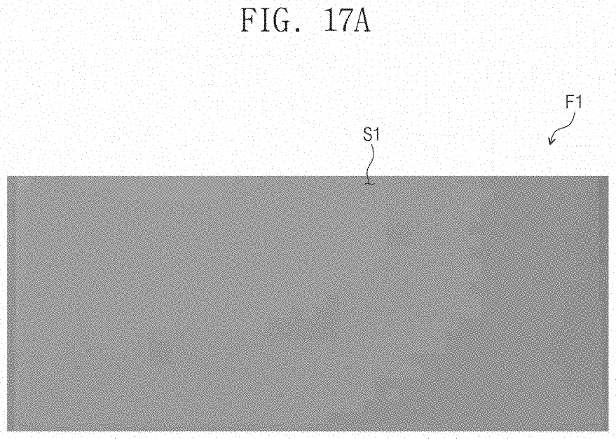

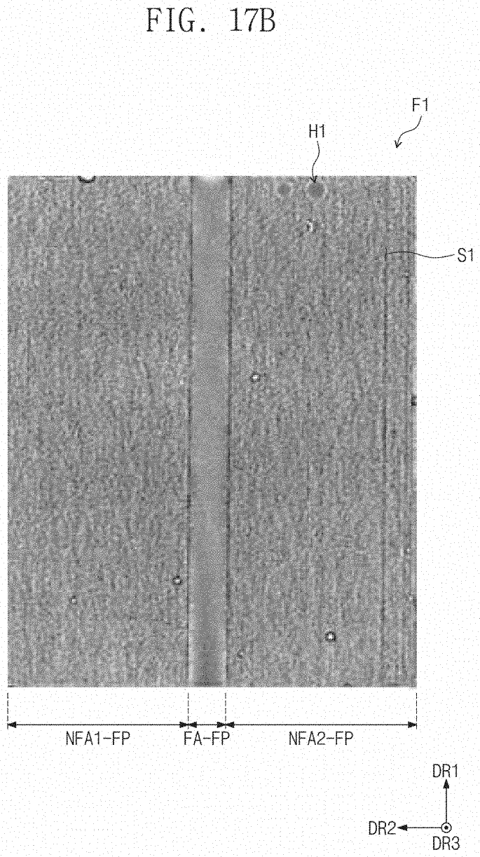

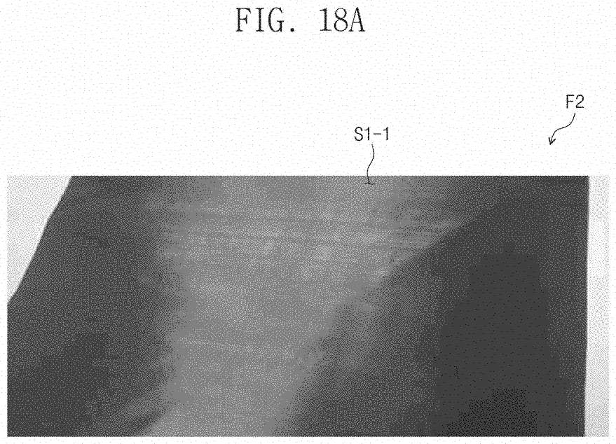

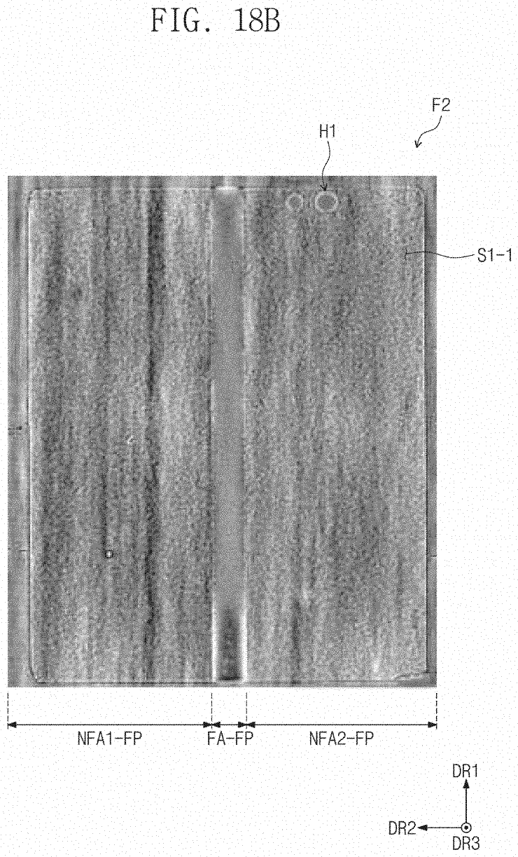

FIG. 17A illustrates the upper surface of the first support portion according to an embodiment of the disclosure, and FIG. 17B is a view illustrating the surface quality of the upper surface of the first support portion according to an embodiment of the disclosure. FIG. 18A illustrates the upper surface of the second support portion according to an embodiment of the disclosure, and FIG. 18B is a view illustrating the surface quality of the upper surface of the second support portion according to an embodiment of the disclosure. In describing FIGS. 17A to 18B, the same or like components as those described above with reference to FIG. 12 will be assigned with the same or like reference numerals, and any repetitive detailed descriptions thereof will be omitted or simplified.

Referring to FIGS. 17A to 18B, the first surface S1 of the first support portion F1 may be a surface facing the display layer 100 (refer to FIG. 10). The first surface 51 may refer to the upper surface of the first support portion F1. The first support portion F1 may include the first material. The first material may include glass fiber reinforced plastic (GFRP).

The first surface S1-1 of the second support portion F2 may be a surface facing the second surface S2 of the first support portion F1. The first surface S1-1 may refer to the upper surface of the second support portion F2. The second support portion F2 may include the second material. The second material may include carbon fiber reinforced plastic (CFRP).

The first material may have higher surface energy than the second material. That is, when FIGS. 17A and 18A are compared with each other, the first uniformity of the first surface S1 of the first support portion F1 may be higher than the second uniformity of the first surface S1-1 of the second support portion F2. Accordingly, when FIGS. 17B and 18B are compared with each other, the first surface quality of the first surface S1 of the first support portion F1 may be higher than the second surface quality of the first surface S1-1 of the second support portion F2.

In a case where a portion of the support part facing the display layer 100 (refer to FIG. 10) includes the second material unlike in an embodiment of the disclosure, the upper surface of the portion of the support part may have relatively low uniformity. In this case, the grains of carbon fibers may be visible on the upper surface of the portion of the support part, and therefore the surface quality may be relatively low. In this case, a bumpy surface may be defined on the surface of the support part that faces the display layer 100 (refer to FIG. 10). That is, the display layer 100 (refer to FIG. 10) disposed on the bumpy surface may fail to provide a flat display surface. According to embodiments of the disclosure, the first support portion F1 including the first material may face the display layer 100 (refer to FIG. 10). The first surface S1 of the first support portion F1 may provide a flat upper surface to the surface attached with the display layer 100 (refer to FIG. 10). The display layer 100 (refer to FIG. 10) may be disposed on the flat upper surface. In such embodiments, the display surface of the display layer 100 (refer to FIG. 10) may be provided to be flat. Accordingly, the electronic device 1000 (refer to FIG. 10) may have improved surface quality.

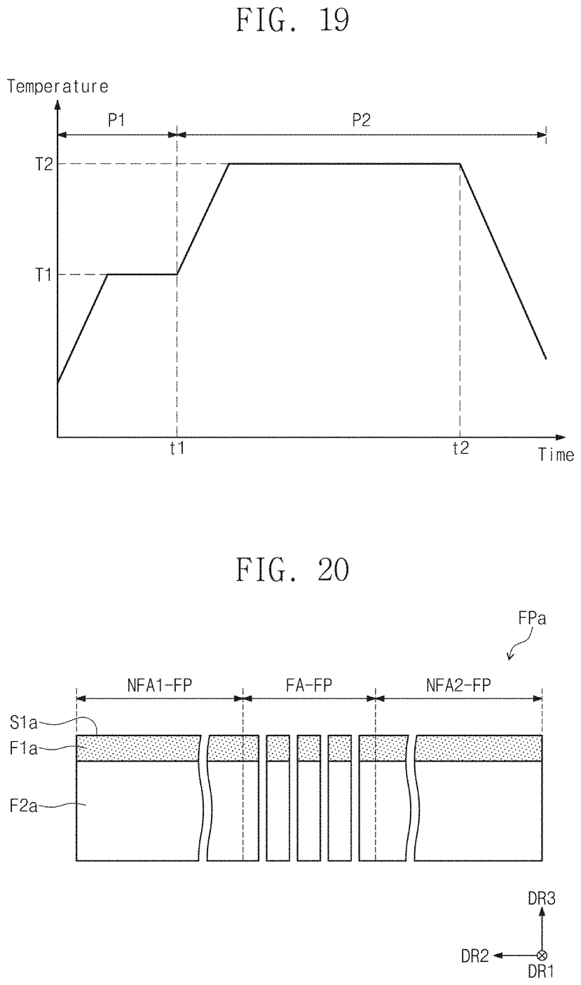

FIG. 19 is a graph depicting the forming temperature of the support part over process time according to an embodiment of the disclosure.

Referring to FIGS. 14 and 19, the support part FP may be formed by a first process P1 and a second process P2.

The first process P1 may include a process in which for the time interval from t=0 to t=t1, temperature is raised to a first temperature T1 and maintained at the first temperature T1. The first temperature T1 may be a temperature at which carbon fiber reinforced plastic is cured. The first temperature T1 may be referred to as the second curing temperature of the second material.

The second process P2 may include a process in which for the time interval from t=t1 to t=t2, the temperature is raised to a second temperature T2 and maintained at the second temperature T2. The second temperature T2 may be a temperature at which glass fiber reinforced plastic is cured. The second temperature T2 may be higher than the first temperature T1. The second temperature T2 may be referred to as the first curing temperature of the first material.

The second support portion F2 may be cured during the first process P1. The second support portion F2 of the support part FP may be first cured. The first surface S1-1 of the second support portion F2 may be relatively non-uniform due to the characteristics of the second material. The first support portion F1 may be disposed between the display layer 100 (refer to FIG. 10) and the second support portion F2. The first support portion F1 may have fluidity during the first process P1. The second surface S2 of the first support portion F1 may compensate for the first surface S1-1 of the cured second support portion F2. The first support portion F1 and the third support portion F3 may be cured during the second process P2. The first support portion F1 may be cured after the second support portion F2 is cured. The first surface S1 of the first support portion F1 may be relatively uniform due to the characteristics of the first material.

According to embodiments of the disclosure, the first support portion F1 may face the display layer 100 (refer to FIG. 10). The first surface S1 of the first support portion F1 may provide a flat upper surface to the surface attached with the display layer 100 (refer to FIG. 10). The display layer 100 (refer to FIG. 10) may be disposed on the flat upper surface. In such embodiments, the display surface of the display layer 100 (refer to FIG. 10) may be provided to be flat. Accordingly, the electronic device 1000 (refer to FIG. 10) may have improved surface quality.

FIG. 20 is a cross-sectional view of a support part according to an alternative embodiment of the disclosure. In describing FIG. 20, the same or like components as the components described above with reference to FIG. 14 will be assigned with the same or like reference numerals, and any repetitive detailed descriptions thereof will be omitted or simplified.

Referring to FIG. 20, an embodiment of the support part FPa may include a first support portion Fla and a second support portion F2a.

The first support portion Fla may have a first surface S1a defined thereon. The first support portion Fla may include the first material. The first material may include glass fiber reinforced plastic. The first surface S1a may face the display layer 100 (refer to FIG. 10). The first support portion Fla may be closer to the display layer 100 (refer to FIG. 10) than the second support portion F2a.

The second support portion F2a may be disposed under the first support portion Fla. The second support portion F2a may include the second material. The second material may include carbon fiber reinforced plastic. The digitizer DGT (refer to FIG. 10) may be disposed under the second support portion F2a.

According to an embodiment of the disclosure, the first support portion Fla including the first material may face the display layer 100 (refer to FIG. 10). The first surface S1a of the first support portion Fla may provide a flat upper surface to the surface attached with the display layer 100 (refer to FIG. 10). The display layer 100 (refer to FIG. 10) may be disposed on the flat upper surface. In such an embodiment, the display surface of the display layer 100 (refer to FIG. 10) may be provided to be flat. Accordingly, the electronic device 1000 (refer to FIG. 10) may have improved surface quality.

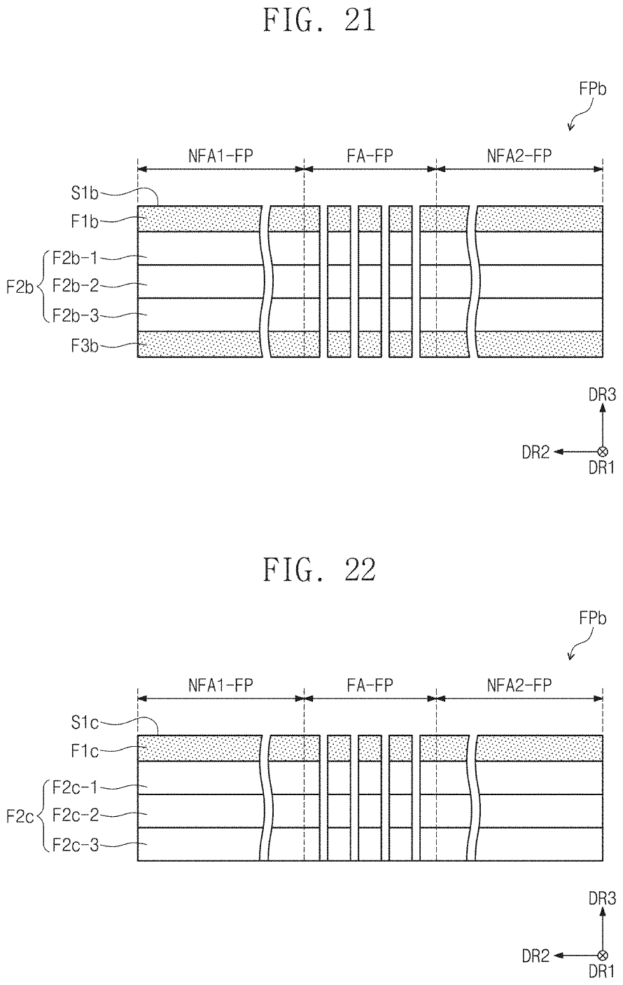

FIG. 21 is a cross-sectional view of a support part according to another alternative embodiment of the disclosure. In describing FIG. 21, the same or like components as the components described above with reference to FIG. 14 will be assigned with the same or like reference numerals, and any repetitive detailed descriptions thereabout will be omitted or simplified.

Referring to FIG. 21, an embodiment of the support part FPb may include a first support portion F1b, a second support portion F2b, and a third support portion F3b.

The first support portion F1b may have a first surface S1b defined thereon. The first support portion F1b may include the first material. The first material may include glass fiber reinforced plastic. The first surface S1b may face the display layer 100 (refer to FIG. 10). The first support portion F1b may be closer to the display layer 100 (refer to FIG. 10) than the second support portion F2b.

The second support portion F2b may be disposed under the first support portion F1b. The second support portion F2b may include fiber reinforced plastic. The second support portion F2b may include a plurality of layers, that is, have a multi-layer structure. The second support portion F2b may include a first layer F2b-1, a second layer F2b-2, and a third layer F2b-3. At least one selected from the first layer F2b-1, the second layer F2b-2, and the third layer F2b-3 may include the first material, and another one selected from the first layer F2b-1, the second layer F2b-2, and the third layer F2b-3 may include the second material. The second material may include carbon fiber reinforced plastic. The first layer F2b-1, the second layer F2b-2, and the third layer F2b-3 may be stacked in the third direction DR3. Although FIG. 21 illustrates an embodiment in which the second support portion F2b includes the three layers, the number of layers included in the second support portion F2b according to an embodiment of the disclosure is not limited thereto. In an alternative embodiment, for example, the second support portion F2b may include two, four or more layers.

The third support portion F3b may be disposed under the second support portion F2b. The third support portion F3b may include the first material. The third support portion F3b may provide a flat lower surface. The digitizer DGT (refer to FIG. 10) may be disposed under the third support portion F3b. The digitizer DGT (refer to FIG. 10) may be disposed under the flat lower surface. Accordingly, the digitizer DGT (refer to FIG. 10) may be easily disposed.

According to an embodiment of the disclosure, the first support portion F1b including the first material may face the display layer 100 (refer to FIG. 10). The first surface S1b of the first support portion F1b may provide a flat upper surface to the surface attached with the display layer 100 (refer to FIG. 10). The display layer 100 (refer to FIG. 10) may be disposed on the flat upper surface. In such an embodiment, the display surface of the display layer 100 (refer to FIG. 10) may be provided to be flat. Accordingly, the electronic device 1000 (refer to FIG. 10) may have improved surface quality.

FIG. 22 is a cross-sectional view of a support part according to another alternative embodiment of the disclosure. In describing FIG. 22, the same or like components as the components described with reference to FIG. 14 will be assigned with the same or like reference numerals, and any repetitive detailed descriptions thereabout will be omitted or simplified.

Referring to FIG. 22, an embodiment of the support part FPc may include a first support portion F1c and a second support portion F2c.

The first support portion F1c may have a first surface S1c defined thereon. The first support portion F1c may include the first material. The first material may include glass fiber reinforced plastic. The first surface S1c may face the display layer 100 (refer to FIG. 10). The first support portion F1c may be closer to the display layer 100 (refer to FIG. 10) than the second support portion F2c.

The second support portion F2c may be disposed under the first support portion F1c. The second support portion F2c may include fiber reinforced plastic. The second support portion F2c may include a plurality of layers. The second support portion F2c may include a first layer F2c-1, a second layer F2c-2, and a third layer F2c-3. At least one selected from the first layer F2c-1, the second layer F2c-2, and the third layer F2c-3 may include the first material, and another one selected from the first layer F2c-1, the second layer F2c-2, and the third layer F2c-3 may include the second material. The second material may include carbon fiber reinforced plastic. The first layer F2c-1, the second layer F2c-2, and the third layer F2c-3 may be stacked in the third direction DR3. Although FIG. 22 illustrates an embodiment in which the second support portion F2c includes the three layers, the number of layers included in the second support portion F2c according to an embodiment of the disclosure is not limited thereto. In an alternative embodiment, for example, the second support portion F2c may include two, four or more layers.

According to an embodiment of the disclosure, the first support portion F1c including the first material may face the display layer 100 (refer to FIG. 10). The first surface S1c of the first support portion F1c may provide a flat upper surface to the surface attached with the display layer 100 (refer to FIG. 10). The display layer 100 (refer to FIG. 10) may be disposed on the flat upper surface. In such an embodiment, the display surface of the display layer 100 (refer to FIG. 10) may be provided to be flat. Accordingly, the electronic device 1000 (refer to FIG. 10) may have improved surface quality.

According to embodiments of the invention, as described herein, the first support portion including the first material may face the display layer. Due to the characteristics of the first material, the first surface of the first support portion may provide a flat upper surface to the surface attached with the display layer, and the display layer may be disposed on the flat upper surface. Accordingly, the display surface of the display layer may be provided to be flat, and the electronic device may have improved display quality.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. An electronic device comprising:
a display layer; and
a support part disposed under the display layer,
wherein the support part includes:
a first support portion having first and second surfaces defined thereon, wherein the first support portion includes a first material, the first surface faces the display layer, and the first surface is closer to the display layer than the second surface is; and
a second support portion facing the second surface, wherein the second support portion includes a second material different from the first material, and
wherein the first material includes a glass fiber reinforced plastic.

2. The electronic device of claim 1, wherein the glass fiber reinforced plastic includes a first resin and a glass fiber disposed in the first resin.

3. The electronic device of claim 2, wherein the glass fiber includes a first fiber extending in a first direction and a second fiber extending in a second direction crossing the first direction.

4. The electronic device of claim 3, wherein the second material includes a carbon fiber reinforced plastic.

5. The electronic device of claim 4, wherein the carbon fiber reinforced plastic includes a second resin and a carbon fiber disposed in the second resin.

6. The electronic device of claim 5, wherein the carbon fiber extends in the first direction.

7. The electronic device of claim 1, wherein the first material has higher surface energy than the second material.

8. The electronic device of claim 1,
wherein the display layer has a first area, a second area, and a third area defined therein,
wherein the second area is spaced apart from the first area in a first direction, and the third area is spaced apart from the first area in the first direction with the second area therebetween,
wherein the support part is disposed under the first area, the second area, and the third area and has a continuous shape, and
wherein a pattern hole is defined in the first support portion overlapping the second area when viewed in a plan view.

9. The electronic device of claim 8,
wherein the pattern hole includes a plurality of pattern holes,
wherein the plurality of pattern holes are spaced apart from each other in the first direction and a second direction crossing the first direction, and
wherein each of the plurality of pattern holes is defined through at least part of the first support portion in a thickness direction of the first support portion.

10. The electronic device of claim 1, wherein the second support portion makes contact with the first support portion.

11. The electronic device of claim 1, wherein the support part further includes a third support portion disposed under the second support portion.

12. The electronic device of claim 11, wherein the third support portion includes the first material.

13. The electronic device of claim 11, wherein the third support portion is spaced apart from the first support portion with the second support portion therebetween.

14. The electronic device of claim 1, wherein a first curing temperature of the first material is higher than a second curing temperature of the second material.

15. The electronic device of claim 1,
wherein the second material includes fiber reinforced plastic, and
wherein the second support portion includes a plurality of layers.

16. The electronic device of claim 1, wherein the first support portion is closer to the display layer than the second support portion is.

17. An electronic device comprising:
a display layer having a folding area and a non-folding area defined therein,
wherein the folding area is foldable about a folding axis, and the non-folding area is adjacent to the folding area; and
a support part disposed under the display layer,
wherein the support part includes:
a first support portion having first and second surfaces defined thereon, wherein the first support portion includes a first material, the first surface faces the display layer, and the first surface is closer to the display layer than the second surface is; and
a second support portion facing the second surface, wherein the second support portion includes a second material different from the first material, and
wherein the first material includes a glass fiber, and the second material includes a carbon fiber.

18. The electronic device of claim 17,
wherein the first material further includes a first resin, and
wherein the glass fiber includes a first fiber extending in a first direction and a second fiber extending in a second direction crossing the first direction.

19. The electronic device of claim 18, wherein the glass fiber is disposed in the first resin.

20. The electronic device of claim 17,
wherein the second material further includes a second resin, and
wherein the carbon fiber extends in a first direction.

21. The electronic device of claim 20, wherein the carbon fiber is disposed in the second resin.

22. The electronic device of claim 17, wherein the first material has higher surface energy than the second material.

23. The electronic device of claim 17, wherein the second support portion makes contact with the first support portion.

24. The electronic device of claim 17, wherein the support part further includes a third support portion disposed under the second support portion.

25. The electronic device of claim 24, wherein the third support portion includes the first material.

26. The electronic device of claim 17, wherein a first curing temperature of the first material is higher than a second curing temperature of the second material.
